(19) United States
(12) Patent Application Publication
(10) Pub. No.: US 2011/0038124 A1
(43) Pub. Date: Feb. 17, 2011

(54) THERMAL INTERCONNECT AND INTERFACE MATERIALS, METHODS OF PRODUCTION AND USES THEREOF

(75) Inventors: Kikue S. Burnham, San Ramon, CA (US); Lea Dankers, Milpitas, CA (US); Martin William Weiser, Liberty Lake, WA (US)

Correspondence Address: HONEYWELL/FAEGRE;Patent Services, 101 Columbia Road, P.O. Box 2245, Morristown, NJ, 07962-2245, US

(73) Assignee: HONEYWELL INTERNATIONAL INC., Morristown, NJ (US)

(21) Appl. No.: 12/988,104

(22) PCT Filed: Apr. 18, 2009
(86) PCT No.: PCT/US09/41052

§ 371 Date: Oct. 15, 2010

Related U.S. Application Data
(60) Provisional application No. 61/046,719, filed on Apr. 21, 2008.

(51) Int. Cl. H05K 7/20; C09K 5/00; B29C 65/52

(52) U.S. Cl. 361/717; 252/73; 252/74; 156/307.1

(57) ABSTRACT

A curable thermal interface material composition includes an epoxy polymeric adhesive matrix; a high conductivity filler; a low melting temperature solder material; and a matrix material modification agent.

### RELATED APPLICATION

This application claims the benefit of U.S. Provisional Application No. 61/046,719, filed Apr. 21, 2008, the subject matter of which is incorporated herein by reference.

### TECHNICAL FIELD

This disclosure relates to thermal interconnect systems, thermal interface systems and interface materials or compositions in electronic components, semiconductor components, other related layered materials applications and methods of making such materials and systems.

### BACKGROUND

Electronic components are used in ever increasing numbers in consumer and commercial electronic products. Examples of some of these consumer and commercial products are televisions, flat panel displays, personal computers, gaming systems, Internet servers, cell phones, pagers, palm-type organizers, portable radios, car stereos, or remote controls. As the demand for these consumer and commercial electronics increases, there is also a demand for those same products to become smaller, more functional, and more portable for consumers and businesses.

As a result of the size decrease in these products, the components that comprise the products must also become smaller. As electronic devices become smaller and operate at higher speeds, energy emitted in the form of heat increases dramatically with heat flux often exceeding 100 W/cm². A popular practice in the industry is to use thermal grease, or grease-like materials, alone or on a carrier in such devices to transfer heat dissipated across physical interfaces and finally to the ambient atmosphere. Most common types of thermal interface materials are thermal greases, phase change materials and elastomer tapes. Thermal greases and phase change materials often have lower thermal resistance than elastomer tapes because of the ability to be spread in very thin layers and provide intimate contact between adjacent surfaces. Typical thermal impedance values range between 0.1-1.6 cm²K/W since this is a strong function of the bondline thickness. However, one drawback of thermal grease is that thermal performance deteriorates significantly after thermal cycling, such as from −65° C. to 150° C., or after power cycling when used in VLSI chips, for example. Common thermal greases use silicone oils as the carrier or matrix. It has also been found that the performance of these materials deteriorates when large deviations from surface planarity causes gaps to form between mating surfaces in electronic devices or when large gaps between mating surfaces are present for other reasons, such as manufacturing tolerances or the like. The performance and reliability of the electronic device in which they are used is adversely affected when the heat transferability of these materials breaks down.

Thus, it could be helpful to provide materials that meet customer specifications while minimizing the size of the device and number of layers, are more compatible with other materials, particularly at interfaces between materials, and have high thermal conductivity and high mechanical compliance.

### SUMMARY

We provide curable thermal interface material (TIM) compositions including an epoxy polymeric matrix; a conductive filler; a solder material; and a matrix material modification agent.

We also provide thermally transmissive electronic components including a first substrate; a second substrate; and a cured composition positioned between the first and second substrates.

We further provide a method of producing a thermally transmissive electronic component including mixing an epoxy polymeric matrix, a conductive filler, a solder material and a matrix material modification agent and forming a curable composition; positioning the composition between a first substrate and a second substrate; curing the polymeric matrix and applying heat to the matrix sufficient to at least partially melt at least a portion of the solder material such that the solder connects to particles in the filler to form a plurality of continuous heat transmissive pathways between the substrates and through the matrix.

### BRIEF DESCRIPTION OF THE DRAWINGS

FIG. 1 is a schematic sectional view of before curing and after curing stages of two different electronic components.

FIG. 2 is a graph showing linear dependence of thermal conductivity on filler loading and the non-linear dependence of the thermal impedance.

FIG. 3 is a graph showing thermal impedance versus bond line thickness.

FIG. 4 is a graph showing temperature dependence of thermal conductivity and thermal impedance of Example 2.

FIG. 5 is a graph showing thermal impedance as a function of applied pressure during curing.

FIG. 6a is a graph showing the viscosity of resulting pastes decreased linearly from 140,000 to 70,000 with the increasing tBPGE.

FIG. 6b is a graph showing thermal conductivity as well as thermal impedance values for tBPGE-added TIMs at Time zero.

FIG. 7 is a graph showing the viscosity of three tBPGE-added samples as a function of time to determine their pot life along with the plot of the non tBPGE-added sample.

FIG. 8a is a graph showing a plot of the maximum cycle count before failure as a function of filler loading for tBPGE-added TIMs.

FIG. 8b is a graph showing thermal impedance versus the number of thermal cycles.

FIGS. 9a and 9b are graphs showing thermal impedance at varying hours of HAST and high temperature aging respectively.

FIG. 9c is a graph showing thermal impedance as a function of the number of reflow cycles.

FIG. 10 is a graph showing vitrification as a function of temperature.

FIG. 11 is a graph showing vitrification as a function of strain.

### DETAILED DESCRIPTION

It will be appreciated that the following description is intended to refer to specific examples of compositions, methods and structures selected for illustration in the description below and in the drawings and is not intended to define or limit the disclosure, other than in the appended claims.

In a typical flip chip package, a heat transfer path is created on the backside of the silicon die through a thermal interface material (TIM1), to a heat spreader, through a second thermal interface material (TIM2), to a heat sink, and eventually to the surrounding ambient atmosphere. The TIM1 fills the gap between the die and the heat spreader to provide a continuous heat transfer path. Since TIM1 is the first interface layer to the heat generating die in contrast to TIM2, which is the second interface layer between heat spreader and heat sink, it is typically the more important heat removal interface.

We found that there are several advantages of using an adhesive TIM over a phase-change material or grease for high power applications. A phase-change material and grease simply wet the contact surface (physical contact). However, the adhesive TIM provides adhesion to a variety of substrates and polar oxide layer of metal fillers via covalent bonding and reduces contact resistance. This property is especially advantageous when the material is subjected to harsh reliability testing such as thermal cycling and humidity testing. Delamination of the TIMs from the substrates due to poor adhesion increases interfacial thermal resistance, reducing heat conduction of the entire package. Thus, the performance of the adhesive TIMs largely depends on the adhesion strength to the die and heat spreader. It also provides mechanical rigidity to withstand mechanical forces during shock and vibration, protecting the die from mechanical damage. Moreover, the crosslinkable adhesive TIM, being more stiff and rigid than soft material such as grease, is known to enhance phonon transfer between fillers and polymers, providing higher overall thermal conductivity.

Our TIMs consider the following material criteria:
1) Thermal conductivity of >12 W/m-K and thermal impedance of <0.05 cm²-K/W at 50 micron bond line thickness for high power application,
2) TIM for metalized substrates (Au) and optionally for bare die,
3) No known health or environmentally sensitive constituents,
4) Application by a variety of methods such as automated dispense needle system or stencil/screening printing,
5) Paste in one part formulation,
6) TIM curing temperature below the board level solder reflow temperature
7) Pass reliability testing: Thermal Cycling (−55° C. to 125° C.), Highly Accelerated Stress Test (130° C., 85% RH, 2 atm absolute pressure), High Temperature Aging (150° C.), and Reflow Cycling (260° C.),
8) Pot life of >3 hours, and/or
9) Manufacturability and cost.

We thus developed a polymer-solder composite as an adhesive TIM. We incorporated a new chemistry in the adhesive resins so that when cured, it would provide filler compatibility and adhesive strength with the contact surfaces. Fillers used are composed of highly thermally conductive metal particles and fusible alloys to form interconnected conductive network by adjoining filler particles within the bulk and/or by forming metallurgical bonding with the surface of the substrate on the metalized substrate. This network formation improves thermal conduction as well as reducing the number of interfacial resistance between fillers/fillers, fillers/polymers, fillers/substrate. The thermal performance of the materials discussed below is characterized by a flash diffusivity method. Thus, the actual values may be different from in-situ performance in a package. The reliability evaluation and the time zero evaluation of thermal performance will be largely focused on data obtained on the metalized substrate.

Our thermal interface material compositions exhibit low thermal resistance, high thermal performance, and maximum surface wetting for a wide variety of interface conditions and demands. The thermal interface materials can, for example, be used to attach heat generating electronic devices (the computer chip, silicon die and the like) to heat dissipating structures (heat spreaders, heat sinks and the like). Performance of the thermal interface materials is an important factor in ensuring adequate and effective heat transfer in such devices.

Our compositions conform to adjacent surfaces (deform to fill surface contours and “wet” the surface), possess a low bulk thermal resistance and possess a low contact resistance. Bulk thermal resistance can be expressed as a function of the composition's thickness, thermal conductivity and area. Contact resistance is a measure of how well a composition is able to transfer heat across the interface which is largely determined by the amount and type of contact between the two materials. We, thus, provide compositions and methods to minimize contact resistance without a significant loss of performance from the materials.

Our compositions comprise at least one matrix material, at least one conductive filler, at least one solder material and at least one material modification agent. Methods of forming these compositions comprise providing each of the at least one matrix material, at least one conductive filler, at least one solder material and at least one material modification agent, blending the components and curing the components pre- or post-application of the thermal interface material to a surface, substrate or component.

The compositions comprise an uncured epoxy polymeric matrix (resin). The epoxy polymeric matrix provides a means of adhering substrates together and provides a mechanism to bring together other components that bring additional functionality to the composition. Each of the substrates can comprise a single layer such as a silicon wafer or can comprise one or more layers such as a gold-coated silicon wafer, for example.

The epoxy polymeric matrix may be made from any number of epoxy-forming materials. For example, an epoxy matrix can be formed from a mixture of bisphenol A and bisphenol B epoxy pre-polymer, a crosslinker such as MHHPA (methylhexahydrophthalic-anhydride), for example, and an epoxy monomer. Well known materials such as epoxy novalac resins may be used. Particularly preferred epoxy novalac resins are EPON. Epoxy novalac resins such as those obtained from Hexion Specialty Chemicals are preferred.

Among the monomers, t-butylphenyl glycidyl ether exhibits good thermal performance because it has a phenyl group and has good chemical compatibility with the main epoxy pre-polymer, which also contains more phenyl groups. This mixture can include, for example: a) 60-70 vol % of metal loading to polymer (representing both conductive filler and solder material amounts), and 0-20 vol % of t-butylphenyl glycidyl ether. The composition comprises an epoxy polymeric matrix, a conductive filler, a solder material, and a matrix material modification agent, comprising about 1 vol % to about 25 vol %, about 1 vol % to about 50 vol %, about 20 vol % to about 50 vol %, or most preferably about 32 vol % to about 37 vol % of the polymeric matrix, based on the volume of the composition.

The epoxy materials should be curable. The epoxy materials can be curable by various methods known in the art. Particularly preferred is heat curing, such as heat curing at about 120° C. to about 170° C. Known curing times applicable to various epoxy materials can be employed such as for about 30 minutes to about 90 minutes. Other curing means can be employed such as with application of various types of radiation such as light or actinic radiation, chemical induced curing such as by a metal initiated polymerization curing or the like may be employed.

The compositions may comprise at least one or a plurality of conductive fillers, such as, for example, tin, bismuth, indium, bismuth-tin alloy, silver metals, indium-tin alloy or combinations thereof that are dispersed in the epoxy polymer matrix. Strong adhesion between the composition and the substrate(s) (such as silicon) is enhanced by addition of a solder material/alloy such as indium-tin alloy in combination with the epoxy polymer matrix. Indium, for example, is an oxygen loving metal and believed to bond with the oxide of a silicon surface, generating indium oxide. Also, we found that epoxy polymers strongly adhere to metal oxides or inorganic oxide surfaces and are better adherers than other thermoset polymeric materials, such as silicone.

One of the benefits of the compositions is that they do not need fluxing agents which are usually used to remove oxides from the solder metal surface. In addition, the compositions demonstrate improved thermal conductivity (thermal impedance) over fluxing agent/silicone-based thermal interface materials designed for metal surfaces.

The conductive filler component may be dispersed in the composition and the filler should advantageously have a high thermal conductivity. Thus, a high conductivity filler should have a thermal conductivity of greater than about 15 and, in some instances, at least about 40 W/m-K. A conductive filler having a thermal conductivity of less than about 15 W/m-K is a low thermal conductivity filler. It is preferred to have a filler component of not less than about 80 W/m-K thermal conductivity. For example, silver and copper fillers both have thermal conductivities of greater than 300 W/m-K and Bi42Sn solder has a conductivity of 19 W/m-K. While Ag, Cu and Bi42Sn solder are all high conductivity fillers, they demonstrate a wide range of thermal conductivity.

Suitable filler materials include, but are not limited to silver, copper, aluminum, and alloys thereof; boron nitride, aluminum spheres, aluminum nitride, silver coated copper, silver coated aluminum, carbon fibers and carbon fibers coated with metals, metal alloys, conductive polymers or other composite materials. Combinations of boron nitride and silver or boron nitride and silver-copper alloy provide enhanced thermal conductivity. Silver and silver-coated copper in amounts of at least about 40 wt % are particularly useful. These materials may also comprise metal flakes or sintered metal flakes. In some examples, the filler components may comprise large silver powders (20 μm) from TECHNIC, medium silver-coated copper (9 μm) from FERRO, small silver powders (3 μm) from METALOR, or combinations thereof.

The composition comprises about 60 vol % to about 80 vol % of the conductive filler, based on the volume of the composition.

The conductive filler component may comprise at least some particles having a diameter less than about 100 μm. The diameter of at least some of those particles may be less than about 80 μm or even about 40 μm.

The conductive filler components also may comprise thermal reinforcement materials, such as screens, mesh, foam, cloth or combinations thereof Thermal reinforcement materials may comprise highly conductive metals, ceramics, composites, or carbon materials, such as low coefficient of thermal expansion (CTE) materials or shape memory alloys. Metal or other highly conductive screen, mesh, cloth, or foam are used to enhance thermal conductivity, tailor CTE, adjust bondline thickness (BLT), and/or modify modulus and thermal fatigue life of the composition. Examples include but are not limited to Cu, Al and Ti foam (e.g., 0.025 to 1.5 mm pore size with 30-90 vol % porosity from Mitsubishi), Cu or Ag mesh or screen (e.g., wire diameter 0.05-0.15 mm, 100-145 mesh from McNichols Co), or carbon/graphite cloth (e.g., 5.7 oz/yd² plain weave, 0.010″ thick, from US Composites).

The thermal reinforcement materials can be treated in a number of ways to improve the performance of the composition. The reinforcement can be pressed or rolled to reduce the thickness and BLT while also increasing the area density of the reinforcement. This is particularly effective with Cu screen. The surface of the reinforcement can be treated to slow the formation of intermetallic compounds due to reaction with the solder component (e.g., plating a Cu mesh with Ni). It can also be treated to enhance wetting of the reinforcement by the solder component (e.g., Ni plating of carbon/graphite cloth or removal of oxides by methods such as exposure to forming gas (hydrogen in nitrogen or argon) at elevated temperature, wash with an acid, or coating with a flux). A flexible frame (e.g., polymer, carbon/graphite, ceramic, metal, composite or other flexible frame) can be used to divide the composition area into smaller areas that behave independently from adjacent areas to compensate for interfacial shear loading issues due to CTE mismatch effects.

Conductive filler components may be coated with by any suitable method or apparatus including, for example, coating the conductive filler components with solder in the molten state, by coating utilizing plasma spray, by plating or by combinations thereof.

The compositions also comprise a solder material. The solder material may comprise, for example, any suitable solder material or metal, such as indium, silver, copper, aluminum, tin, bismuth, lead, gallium and alloys thereof It is preferred that the solder material comprise indium or indium-based alloys.

Solder materials that are dispersed in the composition may be any suitable solder material for a desired application. The composition comprises about 20 vol % to about 50 vol % of the solder material, based on the volume of the composition. Preferred solder materials include, but are not limited to, indium-tin alloys, indium-silver alloys, indium-bismuth alloys, tin-indium-bismuth, indium-tin-silver-zinc, indium-based alloys, tin-silver-copper alloys, tin-bismuth alloys, gallium compounds and gallium alloys. Especially preferred solder materials are those materials that comprise indium. The solder may or may not be doped with additional elements to promote wetting capabilities.

The solder materials are preferably low melting temperature solder materials wherein the solder materials typically melt at temperatures between about 100° C. and about 170° C. Solder materials that have melting temperatures above about 200° C. would be considered high melting temperature solder materials and would be less desirable as the melting temperature increases.

The bismuth-tin alloys may comprise less than about 60 weight percent (wt %) of tin, based on the weight of the alloy. The bismuth-tin alloys may particularly comprise between about 30 and about 60 wt % of tin. The tin-indium-bismuth alloys may comprise less than about 80 wt % of tin, less than about 50 wt % of indium and less than about 15 wt % of bismuth. The tin-indium-bismuth alloys may also comprise between about 40-80 wt % of tin, between about 10-50 wt % of indium and about 2-15 wt % of bismuth. Indium-tin-silver-zinc alloys may comprise less than about 65 wt % of indium, less than about 65 wt % of tin, less than about 10 wt % of silver and less than about 10 wt % of zinc. The indium-tin-silver-zinc alloys may also comprise about 35-65 wt % of indium, about 35-65 wt % of tin, about 1-10 wt % of silver and about 1-10 wt % of zinc.

Additional solder compositions include, but are not limited to, InSn=52% In (by weight) and 48% Sn (by weight) with a melting point of 118° C.; InAg=97% In (by weight) and 3% Ag (by weight) with a melting point of 143° C.; In=100% indium (by weight) with a melting point of 157° C.; SnAgCu=94.5% tin (by weight), 3.5% silver (by weight) and 2% copper (by weight) with a melting point of 217° C.; SnBi=60% Tin (by weight) and 40% bismuth (by weight) with a melting range of 139-170° C., SnInBi=60% Sn (by weight), 35% In (by weight), and 5% Bi (by weight) with a melting range of about 93—about 140° C., and InSnAgZn=50% In (by weight), 46% Sn (by weight), 2% Ag (by weight) and 2% Sn (by weight) with a melting temperature of 118° C.; and BiSn with 58% Bi, 42% Sn (by weight) with a melting temperature of 138° C.

The at least one solder component comprises at least some components having a diameter less than about 40 μm. Preferably, the average component diameter is less than about 40 μm.

The material modification agent includes compounds or compositions that modify the composition to improve thermal performance, compatibility and/or physical quality of the resulting composition, such as by improving the stability of the polymer matrix, decreasing the viscosity of the material, increasing the surface contact or wettability between the composition and the surrounding surfaces, improve elasticity of the composition and resulting layers, tapes or pastes, results in higher thermal filler loading, tailors the curing capability of the composition for the application or a combination thereof The at least one material modification agent may comprise at least one organic compound, at least one modified thermal filler profile, at least one stability additive, at least one viscosity agent and/or combinations thereof.

The material modification agent may include viscosity modifying components that are designed to reduce the viscosity of the epoxy resin to allow a larger volume fraction of metal filler than could be accommodated in conventional applications. Examples of viscosity-modifying components include low molecular weight polymers and epoxy monomer. t-butylphenyl glycidyl ether (tBPGE) and allyl glycidyl ether (AGE) are particularly preferred. The composition comprises an epoxy polymeric matrix, a conductive filler, a solder material, and a matrix material modification agent, wherein the matrix material modification agent is a viscosity modifier, is a mixture of tBPGE and AGE and is about 0 vol % to about 20 vol % tBPGE and about 0 vol % to about 5 vol % AGE, based on the volume of the composition. The viscosity of the composition is thus preferably about 100,000 cps at 25° C. or less.

Another material modification agent includes at least one modified thermal filler. Modified thermal fillers include thermal fillers incorporated into the composition such that the particle size distribution achieves the highest possible volume fraction loading. For example, some of the particles may be larger in diameter, while the remaining particles are significantly smaller in diameter. The average diameter may be the same as a particle size profile that contains all medium sized particles, but by making this modification to the particle size distribution, a deep trough between the peaks in the particle size distribution is formed and higher filler loading is achieved than can be achieved by either a monomodal particle size distribution or one where the through in the particle size distribution is not very deep and the distribution is therefore more uniform.

The thermal performance on various substrates surfaces such as silicon die to nickel plated heat spreader surfaces for our compositions preferably is as follows: a) thermal conductivity of greater than 12 W/m-K, b) thermal conductivity after highly accelerated stress test (HAST) of greater than 10, c) thermal conductivity after reflow of greater than 9, and/or d) thermal conductivity after 100 cycles of a thermal cycling of greater than 10. The composition thus demonstrate excellent thermal performance before and after reliability testing, as well as the initial thermal conductivity.

In addition, the thermal performance on Au-Au (metalized die and spreader surfaces) for the compositions exhibits excellent reliability, passing both 1000 cycles of a thermal cycling and 96 hrs of HAST without meaningful changes in thermal impedance after the test.

The thermal interface materials may also have the following beneficial characteristics: a) stronger adhesion of the epoxy polymer toward the substrate(s), b) further improved adhesion by adding small amounts of solder such as indium-tin alloy, and c) lowered viscosity by using low viscous epoxy resin. Another advantage of the indium-tin alloy is that it provides for good lubricating behavior. These particular materials have higher initial thermal conductivity and better reliability, especially when used for metalized surfaces, such as gold-plated substrates.

The compositions have several advantages directly related to use and component engineering, such as: a) filling small gaps on the order of 0.2 millimeters or less, b) efficiently dissipating heat in those small gaps as well as larger gaps, unlike most conventional solder materials, and c) can be easily incorporated into micro components, components used for satellites, and small electronic components. The compositions also have several advantages directly related to use and component engineering, such as: a) high bulk thermal conductivity, b) metallic bonds may be formed at joining surfaces, thereby lowering contact resistance and c) can be easily incorporated into micro components, components used for satellites and small electronic components.

The composition can be provided as a dispensable paste to be applied by dispensing methods such as, for example, screen printing, stencil printing, automated dispensing and the like and then cured as desired. It can also be provided as a highly compliant, cured, elastomer film or sheet for pre-application on interface surfaces, such as heat sinks It can further be provided and produced as a soft gel or liquid that can be applied to surfaces by any suitable dispensing method, such as screen-printing, ink jet printing or the like. The composition can be provided as a tape that can be applied directly to interface surfaces or electronic components.

It can be useful to utilize stencil printing as a deposition method. However, to dispense paste, liquid or gel by syringes, its viscosity should be lowered while maintaining thermal performance. To this end, the viscosity can be lowered by utilizing at least one of a) lowering the weight percentage of the metal loading to the polymer mixture, b) adding more weight percent of an epoxy monomer with a higher boiling point and/or c) a viscosity modifier. The subtle change in the metal loading to the polymer mixture results in a significant decrease in the viscosity of the mixture. Thus, the components can be mixed and a paste formed. The paste can then be deposited on a substrate such as a die by syringe, covered with a heat spreader and cured.

Compositions and related layers can be formed in any suitable thickness, depending on the needs of the electronic component or other use as long as the thermal interface component is able to sufficiently perform the task of dissipating some or all of the heat generated from the electronic component to which it is attached. Thicknesses may comprise ranges of about 0.030—about 0.150 mm, preferably about 0.050—about 0.100 mm Thicknesses may also be within the wider range of about 0.010—about 0.250 mm in some applications.

In some applications, it may be advisable to reduce the coefficient of thermal expansion mismatch which generates mechanical stresses transferred to, for example, a semiconductor die to prevent cracking the die. This stress transfer can be minimized by increasing the bondline thickness of the composition, reducing the coefficient of thermal expansion of the heat spreader or changing the geometry of a heat spreader to minimize stress transfer. Increasing the bondline thickness generally increases the thermal resistance of the interface, but including a high conductivity mesh as part of a thicker composition can minimize this increase and even result in lower thermal resistance than for the composition alone. Examples of lower CTE materials for heat spreaders are AlSiC, CuSiC, copper-graphite composites, carbon-carbon composites, diamond, CuMoCu laminates and the like. Examples of geometric changes are adding a partial or through slot to the spreader to decrease spreader thickness and forming a truncated, square based, inverted pyramid shape to lower stress and stiffness by having the spreader cross-section be lower near the semiconductor die.

The composition may be applied to a metal-based coating, layer and/or film. Metal-based coating layers may comprise any suitable metal that can be applied to the surface of the composition or surface/support material in a layer. The metal-based coating layer may comprise indium, such as indium metal, InBi alloy, InBiGd alloy and InAg alloy, for example, and can also include nickel and/or gold, among others. These metal-based coating layers are generally applied to a surface by any method capable of producing a substantially uniform layer with a minimum number of pores or voids and can further apply the layer with a relatively high deposition rate. Many suitable methods and apparatus are available to apply layers or ultra thin layers of this type, such as spot plating or pulsed plating. Pulsed plating (which is intermittent plating as opposed to direct current plating) can apply layers that are free or virtually free of pores and/or voids.

The composition can be directly deposited onto at least one of the sides of a heat spreader component, for example, such as the bottom side, the top side or both. Such deposition can be directly onto the spreader or onto a layer on the spreader such as a gold layer, for example. On the other hand, the composition can be deposited onto a die. Such deposition can be direct onto a silicon wafer die or onto a layer on the die such as a gold layer, for example.

The composition may be silk screened, stencil printed, screen printed or dispensed directly onto the heat spreader, die or heat generating device by methods such as jetting, thermal spray, liquid molding or powder spray, and also the common method of paste dispensing via a syringe tipped with a needle or a nozzle. A film of the composition may be deposited and combined with other methods of building adequate thermal interface material thickness, including direct attachment of a preform or silk screening of the composition.

Methods of forming layered compositions include, but are not limited to: a) providing a heat spreader component, wherein the heat spreader component comprises a top surface, a bottom surface and at least one heat spreader material; b) providing at least one composition wherein the composition is directly deposited onto the bottom surface of the heat spreader component; c) depositing, applying or coating a metal-based coating, film or layer on at least part of the bottom surface of the heat spreader component; d) depositing, applying or coating the at least one composition onto at least part of at least one of the surfaces of the heat spreader component or heat generating device, and e) bringing the bottom of the heat spreader component with the composition into contact with the heat generating device, generally a semiconductor die.

Once deposited, applied or coated, the composition layer may comprise a portion that is directly coupled to the heat spreader material and a portion that is exposed to the atmosphere, or covered by a protective layer or film that can be removed just prior to installation of the heat spreader component. Additional methods include, but are not limited to, providing at least one adhesive component and coupling the at least one adhesive component to at least part of at least one of the surfaces of the at least one heat spreader material and/or to or in at least part of the composition. At least one additional layer, including a substrate layer, can be coupled to the layered composition.

Compositions possessing a high thermal conductivity and a high mechanical compliance, e.g., yield elastically or plastically on a local level when force is applied. Compositions possess a high thermal conductivity and good gap-filling properties. When properly produced, the composition spans the distance between the mating surfaces of the heat producing device and the heat spreader component thereby allowing a continuous high conductivity path from one surface to the other surface. Suitable compositions comprise those materials that can conform to the mating surfaces, possess a low bulk thermal resistance and possess a low contact resistance.

Pre-attached/pre-assembled thermal solutions and/or IC (interconnect) packages comprise one or more components of the compositions and at least one adhesive component. These compositions exhibit low thermal resistance for a wide variety of interface conditions and demands. “Adhesive component” means any substance, inorganic or organic, natural or synthetic that is capable of bonding other substances together by surface attachment. The adhesive component may be added to or mixed with the composition, may actually be the composition or may be applied to, but not mixed with the composition. Representative examples of some contemplated adhesive components comprise double-sided tape from SONY, such as SONY T4411, 3M F9460PC or SONY T4100D203. The adhesive may serve the additional function of attaching the heat spreading component to the package substrate independent of the composition.

As briefly noted above, the compositions, along with layered compositions may then be applied to a substrate, another surface, or another layered material. The electronic component may comprise, for example, a composition, a substrate layer and an additional layer. Substrates may comprise any desirable substantially solid material. Particularly desirable substrate layers comprise non-metalized dies or surface, films, glass, ceramic, plastic, metal or coated metal, or composite material. The substrate may comprise a silicon or germanium arsenide die or wafer surface, a packaging surface such as found in a copper, silver, nickel or gold plated leadframe or heat spreader, a copper surface such as found in a circuit board or package interconnect trace, a via-wall or stiffener interface (“copper” includes considerations of bare copper and it's oxides), a polymer-based packaging or board interface such as found in a polyimide-based flex package, lead or other metal alloy solder ball surface, glass and polymers such as polyimide. The “substrate” may even be defined as another polymer material when considering cohesive interfaces. The substrate may comprise a material common in the packaging and circuit board industries such as, for example, silicon, copper, glass, and another polymer. Importantly, the first substrate of a thermally transmissive electronic component may be a heat sink.

Additional layers of material may be applied to the compositions or layered interface materials to build a layered component or printed circuit board. The additional layers may comprise materials similar to those already described herein, including metals, metal alloys, composite materials, polymers, monomers, organic compounds, inorganic compounds, organometallic compounds, resins, adhesives and optical wave-guide materials.

Several methods and many compositions can be utilized to form pre-attached/pre-assembled thermal solution components. A method for forming a thermal solution/package and/or IC package includes: a) providing the thermal interface material or layered interface material; b) providing at least one surface or substrate; c) coupling the at least one composition and/or layered composition to form an adhesive unit; d) coupling the adhesive unit to the at least one surface or substrate to form a thermal package; e) optionally coupling an additional layer or component to the thermal package.

Applications of the thermal solutions, IC packages, thermal interface components, layered interface materials and heat spreader components may comprise incorporating the materials and/or components into another layered material, an electronic component or a finished electronic product. Electronic components are generally thought to comprise any layered component that can be utilized in an electronic-based product. Electronic components may comprise circuit boards, chip packaging, separator sheets, dielectric components of circuit boards, printed-wiring boards, and other components of circuit boards, such as capacitors, inductors, and resistors.

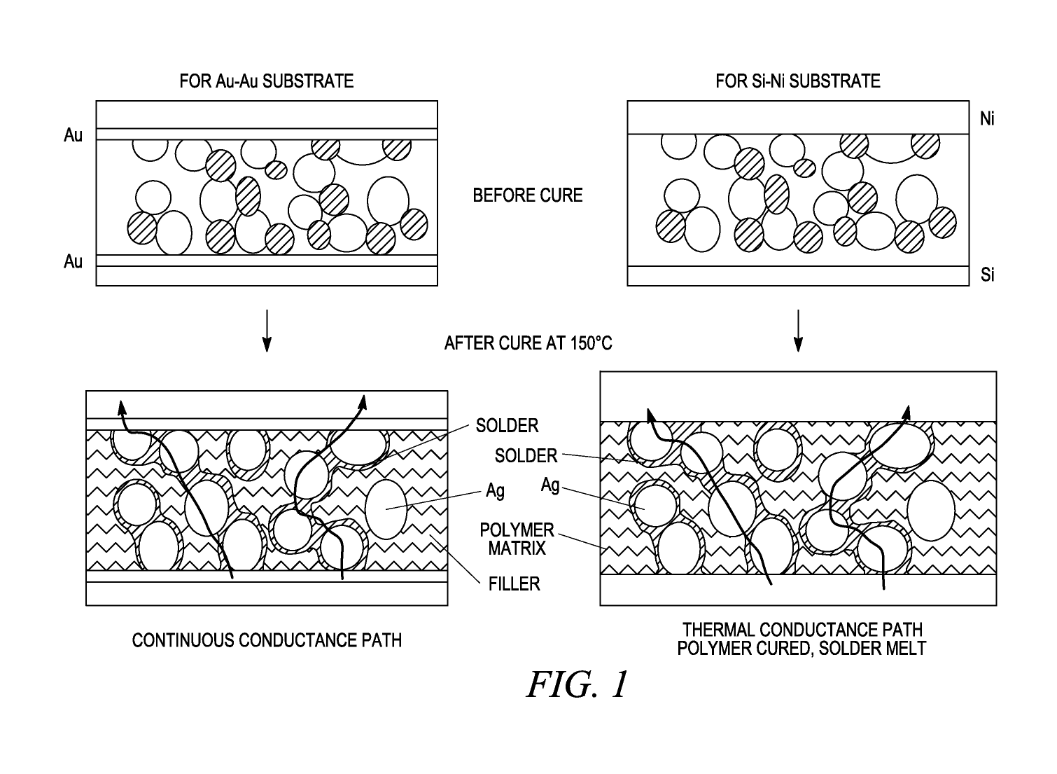

Referring to FIG. 1, it can be seen that two applications of the composition in conjunction with several different types of substrates is illustrated. The lefthand side shows a metallized substrate wherein the metal layers covering the respective substrates area coated with gold. On the other hand, the righthand side shows non-metallized substrates wherein one substrate is a nickel substrate and the other is a silicon substrate such as a silicon wafer.

The top half of FIG. 1 shows the substrates (with or without layers) sandwiching an uncured epoxy resin matrix containing high conductivity filler as shown with the light particles and solder as shown with the dark particles. The matrix modification agent is not separately shown, but is mixed into the epoxy polymer matrix.

The lower portion of FIG. 1 shows the resulting electronic component subsequent to curing. The polymer matrix has cured into a solid matrix and encompasses conductive pathways that are formed from the non-melted high conductivity filler material and melted solder that forms pathways between adjacent filler particles. The solder in some instances surrounds the filler particles and in others does not. However, continuous heat conductive pathways are formed between the opposed substrates and/or metallic layers associated therewith. This structures leads to a good balance of desirable properties.

### Examples

### Materials and Thermal Diffusivity Measurement

Selected amounts of premixed conductive fillers were added to a mixture of crosslinkable resins and subjected to 15 min of high-shear mixing to obtain homogeneous pastes. Thermal diffusivity values were measured by a Netzsch flash diffusivity instrument (LFA 447 NanoFlash™). The well-mixed pastes were applied to the top of the custom stainless steel stencil and a squeegee drawn across to push the material through the stencil openings and print on the metalized heat spreader (ca. 1.27×1.27 cm, 0.77 mm thickness). The die side metallization was applied by sputtering NiV/Au and heat spreader metallization by electroplating Ni/Au on the Cu substrate. The same substrate type was used for the thermal diffusivity measurements unless otherwise specified. A fixture was used to hold the substrate and maintain uniform positioning. The die (ca. 1.27×1.27×0.53 mm thickness) was placed on top of the printed paste and placed in a fixture designed to keep the sandwich aligned during curing. The sandwich composed of the heat spreader, paste of thermal interface materials, and die was placed in oven and cured at 160° C. for 45 min at pressure of 20 psi. The typical bond line thickness achieved was in the 45-55 micron range unless otherwise specified. A micrometer was used to measure the thickness. Both sides of the resulting solid composite sandwiches were coated with a thin layer of graphite to provide the high emissive surfaces required for flash diffusivity measurements. The front surface of the square samples was irradiated uniformly with xenon pulse. The time-dependence of the temperature-change at the rear surface was monitored by a liquid nitrogen-cooled InSb infrared detector. Specific heat capacities were measured with a differential scanning calorimeter. Bulk densities were calculated from weights and dimensions of the samples. Finally, effective thermal conductivity (K) was calculated from thermal diffusivities (ρ), specific heat capacities (Cₚ), and densities (α) of the films using the following equation,

K=ραCₚ Eq. 1.

A mathematical model was used to best fit the half-rise time and determine the sample's diffusivity, with inputs of the thickness and density. Instrument error was estimated to be +/−3%. The thermal conductivity values presented were “effective” thermal conductivity, as opposed to “bulk” thermal conductivity, unless otherwise specified. Note that for a given material, the bulk thermal conductivity is always larger than the effective thermal conductivity since the effective thermal conductivity includes the interfacial resistances between TIM and die or heat spreader. Thermal conductivity measurements were taken at 65° C. unless otherwise specified. Thermal impedance (Z) at one thickness (d) was calculated according to equation,

Z=d/K Eq. 2.

Note that for any one sample, the interface impedance is not expected to be spatially uniform. Because the measurement involves the sample as a whole, the impedance values showed must be regarded as averages over the total cross-sectional area. All samples were prepared in the same procedure unless otherwise specified.

### Thermal Conductivity

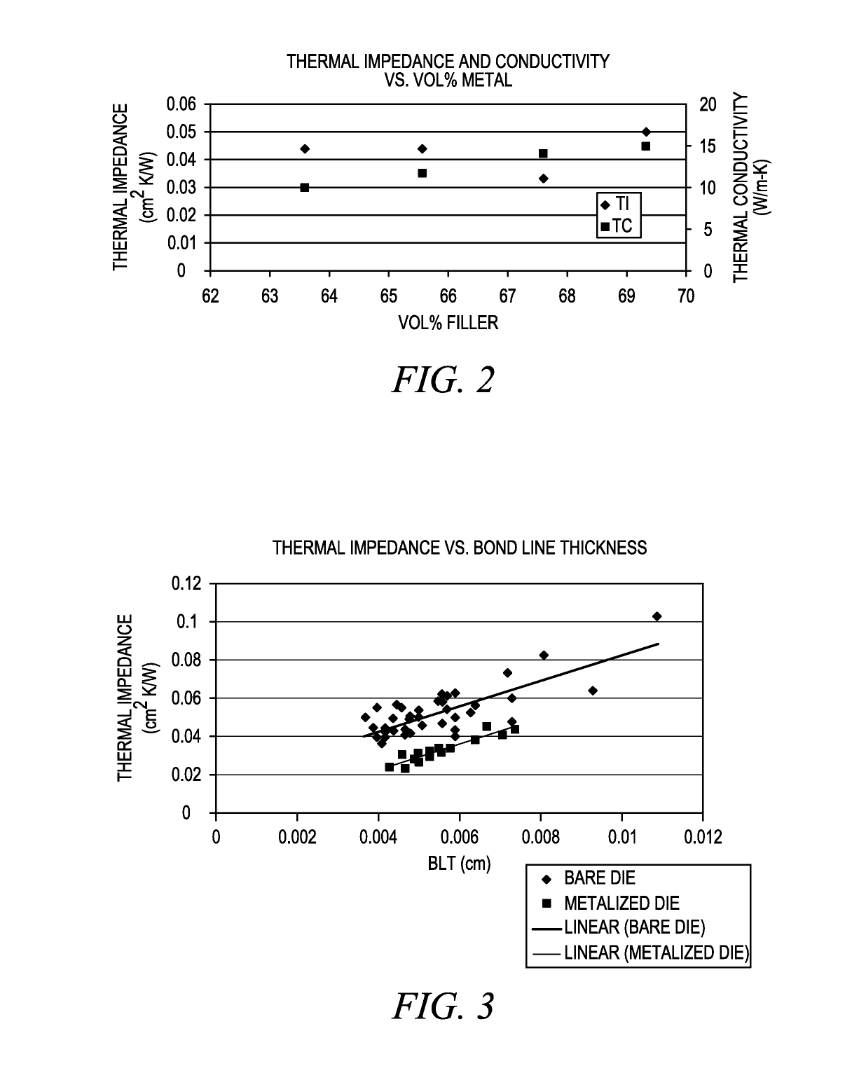

We first sought to achieve high thermal conductivity by increasing filler loading while maintaining the appropriate viscosity of the paste to be dispensable. A series of materials were prepared with the fillers loadings between 63.6 and 69.3 vol %. Example 1 corresponds to filler loading of 67.7 vol %. FIG. 2 shows a linear dependence of the thermal conductivity on the filler loading. The highest value is achieved with ˜69.3 vol % loading with a value of K=15 W/m-K. The corresponding inverse linearity of the thermal impedance was observed up to 67.7 vol %. The sudden jump at the 69.3 vol % is a result of larger bond line thickness since the paste at or above the filler loading was not easily printable due to the increased viscosity. On the other hand, samples below 63 vol % loading were destroyed before the measurement due to “bleed-out” of the liquid resins during curing.

Thermal impedance is a more accurate measurement of performance than thermal conductivity alone since true performance of a TIM should depend on the quality of heat conduction through the TIMs and the quality of contact between the TIMs and the two mating surfaces. A plot of thermal impedance as a function of thickness for Example 1 is shown in FIG. 3. The effective thermal conductivity and thermal impedance is 14.0 W/m-K and 0.03 cm²-K/W at 50 micron, respectively using metalized die. The bulk thermal conductivity calculated from the line's slope showed ˜15 W/m-K.

The interface impedance (contact resistance) extrapolated at the zero-thickness intercept of the straight line showed almost zero, indicating the excellent heat conduction at the interface. As expected, this high thermal conductivity is attributed to the conductive network structures formed during curing, thereby providing thermal conductive pathways through the bulk of the TIM. This is turn enhances the heat conduction between the two interfaces. The low contact resistances at two interfaces on the metalized die and the heat sink are due to metallurgical bonding. Example 1 was also tested on bare die back to see its performance. The results from the plot in FIG. 3 shows a bulk thermal conductivity, thermal impedance at 50 micron, and interface impedance of ˜15 W/m-K, ˜0.05 cm²-K/W, and ˜0.02 cm²-K/W respectively. Comparing the results, we conclude that the bulk heat conduction performance is similar for the TIM regardless of the substrate surfaces, which is in marked contrast with the results previously obtained in analogue TIMs in which a different adhesive polymer is used. In that case, a 60% decrease in the thermal conductivity as well as thermal impedance was observed on the bare Si die compared to that on the metalized die. It is clear that Example 1 can be used on a variety of surfaces; however, our focus here will be directed to the application on the metalized die.

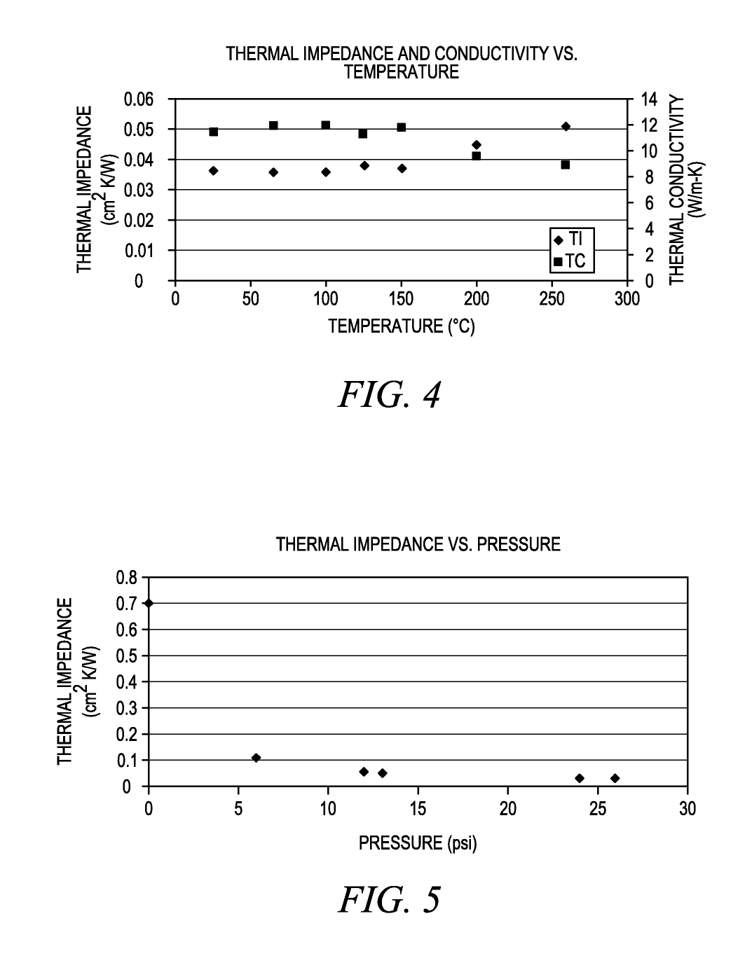

FIG. 4 shows the temperature dependence of the thermal conductivity of Example 2. The thermal conductivity is found to not change with the temperature up to 150° C. This is expected since the microstructure of the bulk TIM as well as interface should not change in this temperature range. In general, most of the computer processors operate at 80-120° C., thus Example 2 which maintains the higher thermal conductivity, 12 W/m-K, even at the operating temperature can ensure efficient heat transfer. At 200° C., a 25% decrease in thermal conductivity and associated increase in thermal impedance was observed. At this temperature, it is believed that part of the composite may become soft due to the melting of fusible fillers. The decrease in the thermal conductivity may be related to the thermal material degradation or inefficient phonon transfer due to loss of rigidity of the composite.

### Effect of Curing Conditions

To enhance thermal interface properties, it is important to have proper curing conditions of TIM materials. We investigated the effect of applied pressure on the thermal impedance during curing and of curing temperature. The curing time is kept the same in both tests. Applying pressure on samples during curing can improve the TIM contact to the substrate surface and reduce the bond line thickness, thus reducing the thermal resistance. FIG. 5 shows the thermal impedance as a function of applied pressure during curing. As expected, thermal impedance decreases when the pressure increases, reaching a steady state after applying 24 psi. A sharp drop of thermal impedance between a no-pressure applied sample and a sample with pressure of 6 psi was observed. The drops may result from multiple effects on the material properties such as the morphological change, reduction of porosity, and densification of the bulk as well as the reduction of voids or air gaps at the interfaces.

Table 1 shows the effect of curing temperature on the thermal conductivity of all three APS-a samples. We selected three different curing temperatures:
120° C., 45 min cure
120° C., 45 min cure, with a 160° C., 45 min postcure
160° C., 45 min cure.

TABLE 1

| Material ID | Metal vol % | 120 C. | 120/160 C. | 160 C. |
|---|---|---|---|---|
| APS-a636 | 63.6 | 3.4 | 4.7 | 10 |
| APS-a656 | 65.6 | 4.4 | 5.6 | 12 |
| APS-a677 | 67.6 | 7.9 | 6.5 | 13.9 |

An 80% increase in thermal conductivity of 160° C. cured samples compared to samples cured at two other curing conditions. No enhancement in thermal conductivity of the step-cured sample (120° C., 160° C. postcure) compared to that of 120° C. cured sample indicates that time scale of two processes; hardening of polymer due to crosslinking and melting of the fusible alloys must be well balanced. In other words, melting of the alloys occurs prior to the completion of hardening of the polymer matrix to form a more continuous conduction path.

### Viscosity Modification

Our TIMs should be easily applied by a variety of methods such as automated dispense needle system and stencil/screening printing. Moreover, TIMs should have good pot life to increase the process window. Thus, minimizing the viscosity and increasing pot life of TIMs are important in improving the processability and reducing the bond line thickness of the thermal interface layer. Since the filler volume has a large effect on the viscosity of TIMs, the viscosity of the paste with different filler loading was measured with Haake rheometer at 25° C. at shear rate of 1/25 s using a 20 mm cone and plate geometry. It showed a linear dependence of the filler loading over the range we investigated, already approaching 132,000 cps even at filler loading of 63.6 vol %. The filler loading to obtain a viscosity of 100,000 cps, our target viscosity, is calculated to be 61.7 vol % at which the thermal conductivity is extrapolated to be ˜8 W/m-K.

The pot life was determined as time until a 10% increase in the viscosity from time zero when the paste is left under ambient conditions.

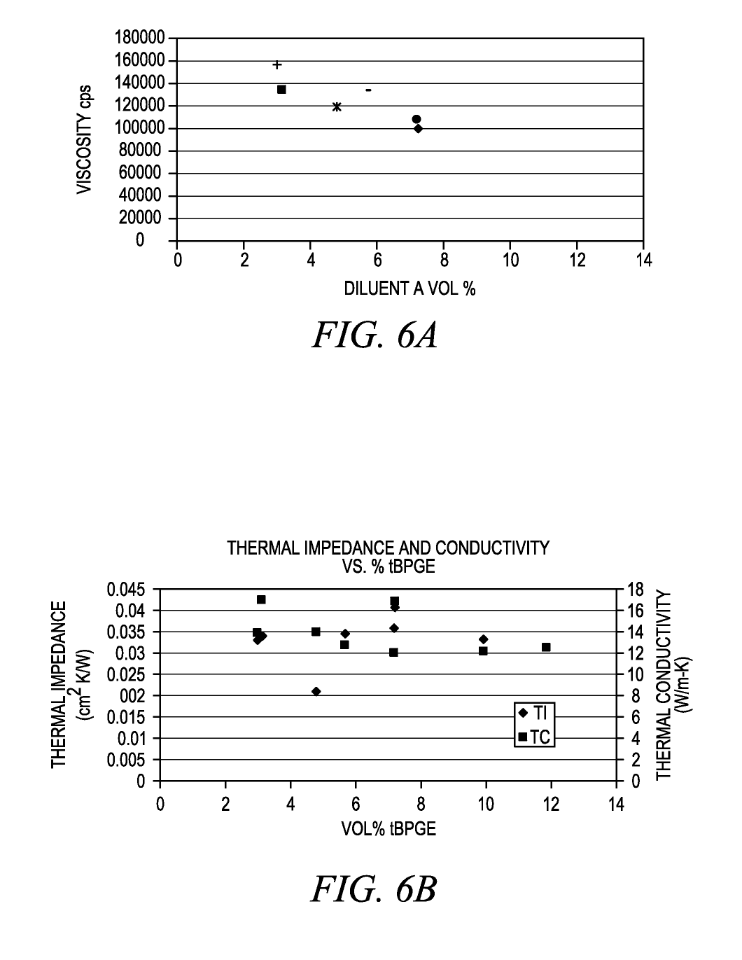

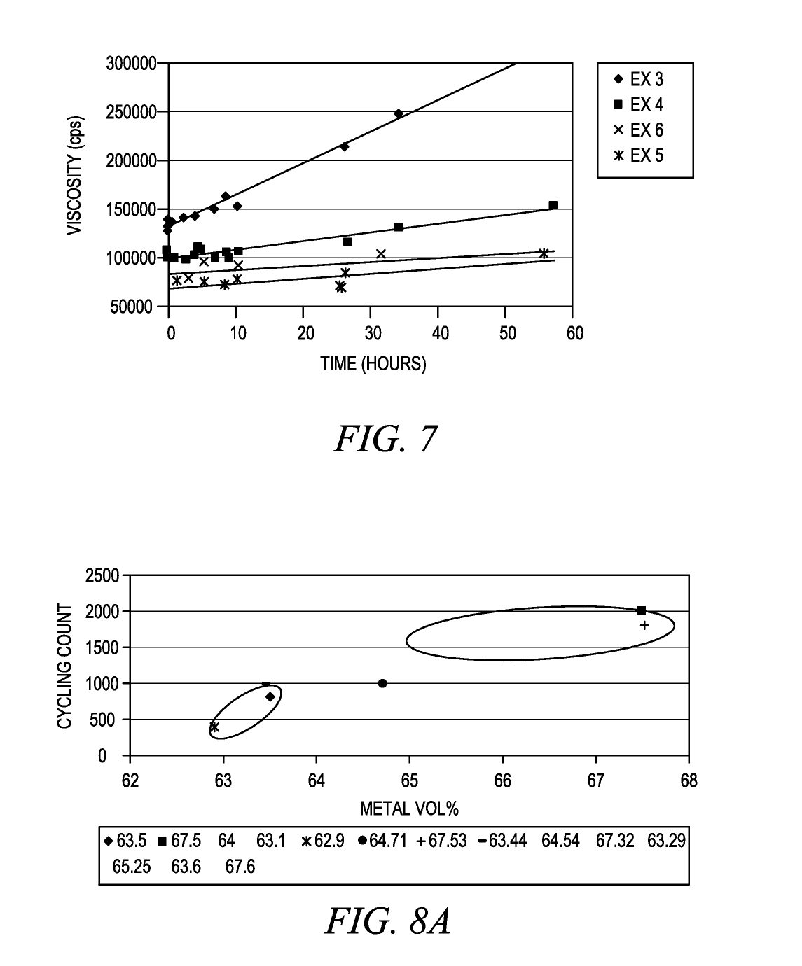

For manufacturing throughput consideration, the paste should be in one part formulation, not requiring any mixing prior to the dispensing as opposed to two part formulations. For the viscosity reduction, we prepared a series of the resin mixtures having various concentrations of a Diluent A (tBPGE) mixed with various amount of the fillers. The Diluent A functioned as a viscosity modifier as well as an end-capping and increased a pot life. However, the viscosity of the resulting paste is again largely dominated by filler loading over a range of the diluent we investigated. Thus, we decided to investigate the effect of the diluent amount at the same filler loading (64 vol %, +/−0.3%). As seen in FIG. 6a, the viscosity of the resulting pastes, indicated by the different symbols in FIG. 6A, decreased linearly from 140,000 to 70,000 with the increasing diluent amount. It can be seen that at that filler loading, the incorporation of more than 7 vol % of the diluent is required to decrease the viscosity to <100,000 cps as demonstrated by Examples 4-6. The thermal conductivity as well as thermal impedance values for all the diluent-added TIMs at Time zero was similar and well within the specification, as shown in FIG. 6b. FIG. 7 shows the viscosity of those three diluent-added samples as a function of time to determine their pot life along with the plot of the non diluent-added sample. Example 7 (similar to Example 1 but with 93.5% metal) at the similar metal loading. The pot life of the three diluent-added samples is significantly increased, indicated by a relatively modest increase in their viscosity over time, as opposed to a significant increase for non diluent-added sample, for the same filler loading. The viscosity, pot life, and the thermal performance of all samples with and without Diluent A were summarized in Table 2. The increase in pot life with increasing Diluent A amount is most probably due to the slowing of the polymer crosslinking reaction.

TABLE 2

| | | | Viscosity | | Time | |
|---|---|---|---|---|---|---|
| | | | (cps at | | zero | |
| | Metal | | 1/25 s, | | TC | Time zero |
| Material | loading | Diluent | 25° C., | Pot life | (W/m- | TI |
| ID | Vol % | A vol % | Time zero) | hrs | K) | (cm²K/W) |
| Ex 1 | 67.6 | 0 | 180,000 | <<3 | 14.0 | 0.033 |
| Ex 2 | 65.6 | 0 | 154,000 | ~4 | 11.6 | 0.037 |
| Ex 3 | 63.6 | 0 | 132,000 | ~4 | 9.85 | 0.043 |
| Ex 4 | 63.7 | 7.22 | 104,404 | ~12 | 10.9 | 0.041 |
| Ex 5 | 63.2 | 11.9 | 71,702 | ~14 | 12.6 | 0.033 |
| Ex 6 | 63.3 | 9.94 | 74,664 | ~12 | 11.8 | 0.033 |

### Thermal Cycling

After the thermal performance evaluation at Time zero, the samples regardless of their viscosity were stressed through one round of thermal cycling evaluation from −55 to 125° C., using a single chamber system. The thermal conductivity of the samples was measured at intervals of 200 cycles up to 2000 cycles or until failing. We defined the cycling failures as when 15 percent of the total samples reach thermal impedance above 0.05 cm²-K/W. FIG. 8a shows a plot of the maximum cycle count before failure as a function of filler loading. It can be seen that some of the diluent-added samples showed thermal degradation at low cycle count (each symbol represents a different composition and the elliptical shapes identify compositions tolerating higher cycle amounts or lower cycle amounts). The degradation with cycling does not seem to be directly dependent on the amount of the diluent, but on the filler loading. Below 65 vol %, some of the samples were starting to show failures after 400 cycles. On the other hand, a non diluent-added samples showed no filler loading dependency and Example 1 showed the best performance with almost no degradation up to at least 2000 cycles as shown in FIG. 8b when the test was terminated. It is not clear at this point why the earlier thermal degradation occurred for only diluent-added samples with lower filler loading, but we believe that the fillers may play an important role in the cured polymer structure or polymer curing in the presence of the additive.

### HAST, Temperature Aging, and Reflow Cycling

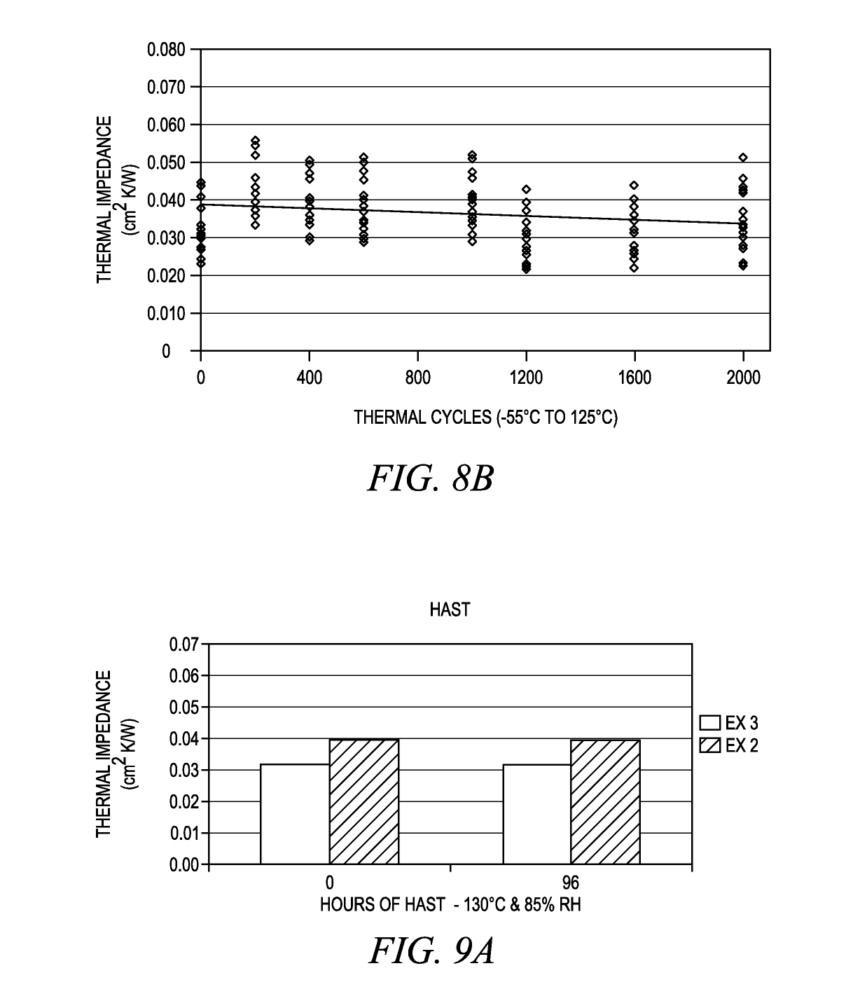

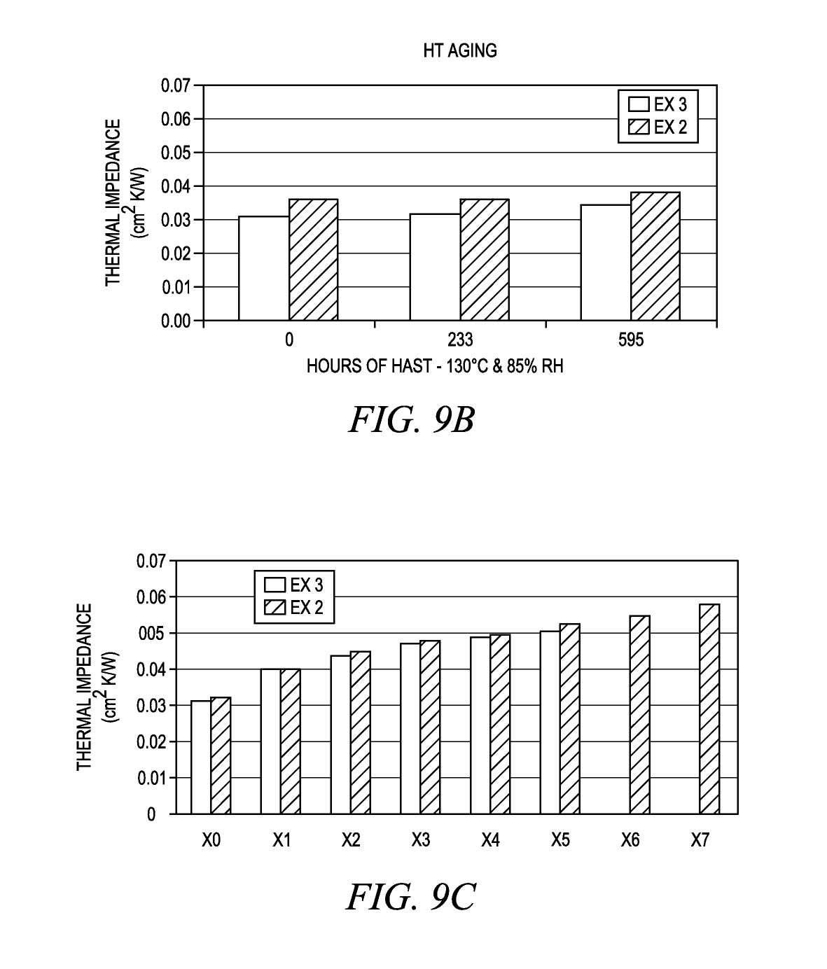

Based on all the above results, both the filler and additive loading were carefully configured to give the final formulation Example 3. Examples 2-3 were subjected to Highly Accelerated Stress Test (HAST), High Temperature Aging, and Reflow Cycling as shown in FIGS. 9a-c, respectively. To accelerate penetration of moisture along the interface and within the bulk material, the TIMs were tested for HAST (85° C., 85% RH and 2 atm absolute pressure). If the material has significant amount of free volume in the bulk or is hygroscopic, then it would take up moisture and cause delamination from the substrates. Both TIMs showed a tight distribution with no degradation after 96 hours, indicating that they are stable under the moisture stress environment. To accelerate thermal stress, the samples were put in an over and heated at a temperature of 150° C. for longer durations. Both TIMs showed no change in thermal impedance at the end of 600 hours, indicating the thermal stress induced at this temperature and duration is not an issue. To determine if the TIM can tolerate the high temperature of solder reflow, they ere subjected to 5 to 7 reflow cycles at a peak temperature of 260° C. Gradual degradation was observed, but this was within our limit after 3 reflow cycles. Delamination of the TIMs from the interfaces was not observed based on the SEM analysis. Overall, the thermal impedance of both TIM remained relatively constant throughout the various stress tests.

### CSAM

To understand the quality of the bonded interface after curing, an acoustic scan of Example 7 cured on a gold metalized die in a flip-chip test assembly. Bright areas on the whole die surface indicate that this material provides the excellent adhesion with the surfaces.

### Strain Sweep

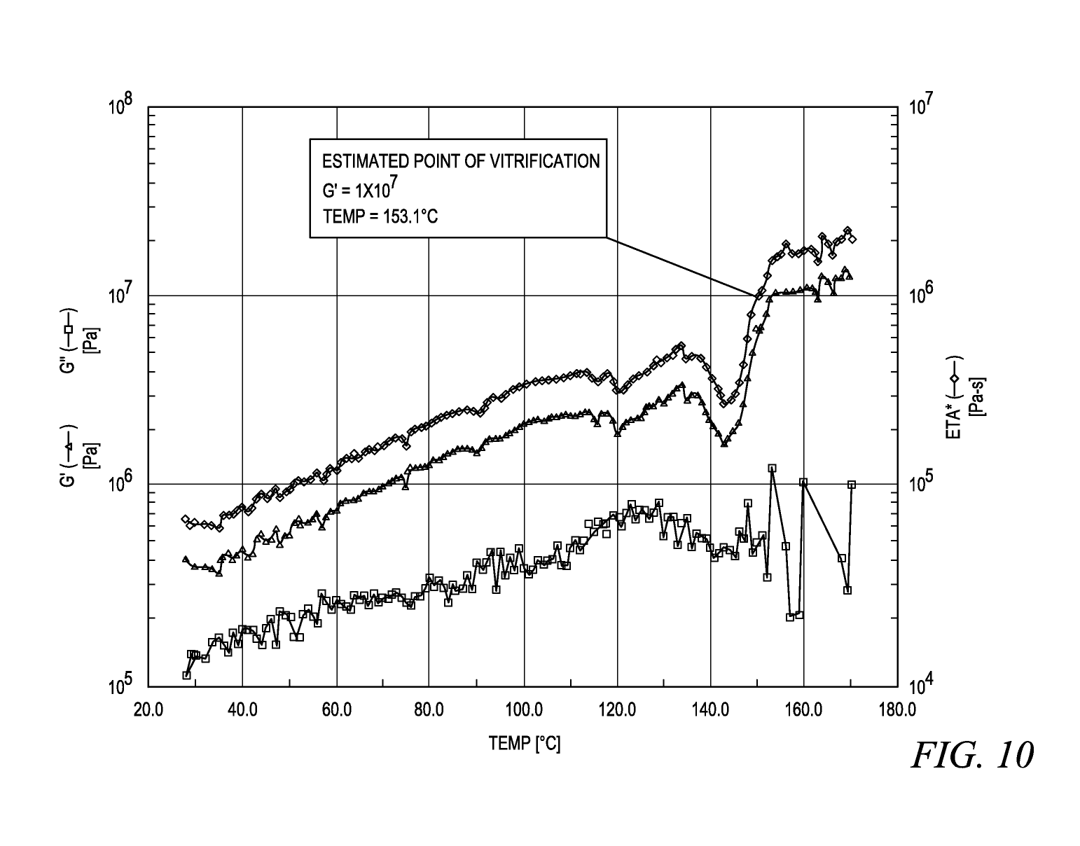

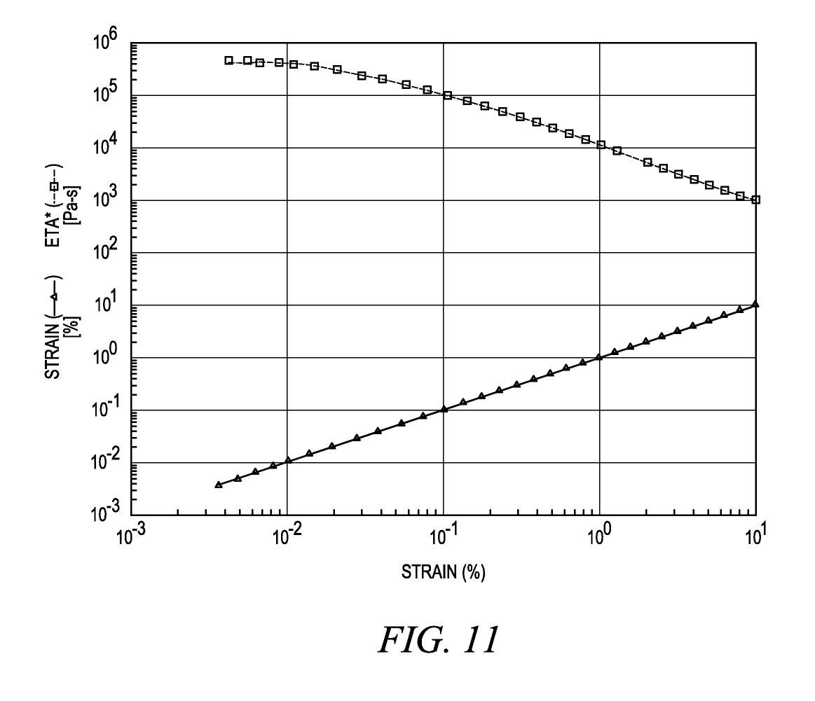

We also conducted strain sweep testing on Example 2. Results are shown in Table 3 and FIGS. 10-11. We used the following testing protocol:

| | |
|---|---|
| Instrument: | Rheometric Dynamic Analyzer Model |
| | 3 (RDAIII) |
| Calibration Procedure: | Calibrated transducer in torsion and |
| | normal direction using 500 gram |
| | weight |
| Sample Atmosphere/Rate: | Subambient: Liquid Nitrogen, |
| | Elevated: Compressed Air/5 cfm |
| Parallel Plate Diameter (mm) : | 25.0 |
| Gap Setting (mm): | 2.0 |
| Frequency (Hz): | 1.0 |
| Strain (%): | 0.01 |
| Sample Preparation: | Tested as received. Stored at −40° C. |
| | until 30 minutes prior to testing |
| Material Drying Parameters: | Not required |
| Test temperature (° C.): | 30 to 170 |

FIG. 10 shows that both the shear modulus and the complex shear modulus increase with temperature except for a dips just above 120° C. and 140° C. where the solders melt. They do not cross during this temperature sweep. FIG. 11 shows the complex viscosity as a function of strain showing a monotonic decrease with increasing strain.

TABLE 3

| Temp | Exp⁺ | G′ | G″ | | Torque | | |
|---|---|---|---|---|---|---|---|
| ° C. | Pa · s | Pa | Pa | tan, delta | g · cm | Strain % | time % |
| 29.5 | 7.0397E+04 | 4.18E+05 | 1.45E+05 | 0.3483 | 1.0 | 0.008 | 8 |
| 28.2 | 7.5925E+04 | 4.64E+05 | 1.13E+05 | 0.2433 | 1.1 | 0.007 | 38 |
| 30.1 | 7.0757E+04 | 4.21E+05 | 1.30E+05 | 0.3383 | 1.1 | 0.008 | 89 |
| 32.3 | 7.0053E+04 | 4.03E+05 | 1.70E+05 | 0.3383 | 1.1 | 0.008 | 190 |
| 33.8 | 6.9597E+04 | 3.52E+05 | 1.70E+05 | 0.4283 | 1.0 | 0.008 | 129 |
| 35.0 | 6.7048E+04 | 4.53E+05 | 1.76E+06 | 0.4258 | 1.0 | 0.007 | 188 |
| 38.1 | 7.7772E+04 | 4.52E+05 | 1.47E+05 | 0.4399 | 1.1 | 0.007 | 180 |
| 33.2 | 8.0173E+04 | 4.54E+05 | 1.63E+05 | 0.3499 | 1.1 | 0.007 | 223 |
| 38.1 | 7.8202E+04 | 4.73E+05 | 1.94E+05 | 0.3094 | 1.1 | 0.007 | 248 |
| 33.2 | 7.9620E+04 | 5.05E+05 | 1.85E+05 | 0.3440 | 1.1 | 0.007 | 278 |
| 40.1 | 8.6183E+04 | 4.87E+05 | 1.92E+05 | 0.3830 | 1.0 | 0.007 | 330 |
| 41.1 | 8.3106E+04 | 4.86E+05 | 1.74E+05 | 0.4107 | 1.1 | 0.007 | 320 |
| 42.1 | 8.0535E+04 | 5.76E+05 | 1.82E+05 | 0.3943 | 1.2 | 0.007 | 358 |
| 43.2 | 8.3106E+04 | 6.09E+05 | 1.99E+05 | 0.3027 | 1.3 | 0.007 | 491 |
| 44.1 | 9.5840E+04 | 5.54E+05 | 2.78E+05 | 0.2585 | 1.3 | 0.007 | 428 |
| 45.1 | 1.0036E+04 | 5.74E+05 | 2.10E+04 | 0.2575 | 1.3 | 0.007 | 430 |
| 46.1 | 9.3590E+04 | 4.452E+05 | 2.27E+05 | 0.3823 | 1.3 | 0.007 | 430 |
| 47.3 | 9.7734E+04 | 5.32E+05 | 2.23E+02 | 0.2483 | 1.4 | 0.007 | 529 |
| 48.3 | 1.0535E+04 | 5.99E+05 | 1.74E+05 | 0.4423 | 1.3 | 0.007 | 520 |
| 49.1 | 9.3737E+04 | 6.90E+05 | 1.73E+05 | 0.3810 | 1.4 | 0.007 | 548 |
| 50.1 | 1.0133E+04 | 7.01E+06 | 2.30E+05 | 0.3710 | 1.5 | 0.006 | 579 |
| 51.1 | 1.0181E+04 | 7.20E+06 | 2.43E+06 | 0.2481 | 1.5 | 0.006 | 808 |
| 52.1 | 1.1493E+04 | 6.81E+06 | 2.22E+06 | 0.2424 | 1.5 | 0.006 | 838 |
| 53.1 | 1.1791E+04 | 6.80E+06 | 2.08E+06 | 0.3370 | 1.5 | 0.006 | 590 |
| 54.1 | 1.1440E+04 | 7.19E+06 | 2.83E+06 | 0.3524 | 1.5 | 0.006 | 538 |
| 55.1 | 1.1635E+04 | 7.82E+06 | 2.22E+05 | 0.3394 | 1.7 | 0.006 | 729 |
| 56.1 | 1.1978E+04 | 6.54E+06 | 2.43E+05 | 0.2237 | 1.8 | 0.006 | 758 |
| 57.1 | 1.2870E+04 | 7.48E+06 | 2.73E+05 | 0.4483 | 1.8 | 0.006 | 759 |
| 58.1 | 1.1411E+04 | 8.16E+06 | 2.59E+05 | 0.3552 | 1.8 | 0.006 | 818 |
| 59.1 | 1.2850E+04 | 7.78E+06 | 2.49E+05 | 0.2934 | 1.8 | 0.006 | 818 |
| 60.1 | 1.3553E+04 | 6.73E+06 | 2.39E+06 | 0.3471 | 1.9 | 0.006 | 819 |
| 61.1 | 1.3102E+04 | 9.19E+06 | 2.73E+06 | 0.2983 | 1.9 | 0.006 | 908 |
| 62.3 | 1.4483E+04 | 9.35E+06 | 2.81E+06 | 0.2732 | 1.9 | 0.006 | 978 |
| 63.1 | 1.5105E+04 | 4.18E+06 | 2.51E+06 | 0.2660 | 1.9 | 0.006 | 998 |
| 64.1 | 1.4651E+04 | 6.95E+06 | 2.75E+05 | 0.3080 | 2.0 | 0.006 | 1039 |
| 66.1 | 1.5578E+05 | 1.00E+06 | 2.81E+05 | 0.2800 | 1.0 | 0.006 | 1059 |
| 66.3 | 1.4894E+05 | 4.18E+06 | 2.75E+05 | 0.2484 | 2.1 | 0.006 | 1023 |
| 66.1 | 1.6528E+05 | 1.04E+06 | 2.72E+05 | 0.2947 | 2.1 | 0.005 | 1118 |
| 68.1 | 1.6172E+05 | 1.11E+06 | 2.85E+05 | 0.2578 | 2.0 | 0.005 | 1148 |
| 69.1 | 1.4569E+05 | 1.04E+06 | 2.92E+05 | 0.2647 | 2.2 | 0.005 | 1178 |
| 70.1 | 1.0897E+05 | 1.07E+06 | 2.73E+05 | 0.2451 | 2.2 | 0.005 | 1228 |
| 71.1 | 1.7085E+05 | 1.11E+06 | 2.59E+06 | 0.2553 | 2.3 | 0.005 | 1238 |
| 72.1 | 1.8246E+05 | 1.13E+06 | 2.49E+05 | 0.2479 | 2.3 | 0.005 | 1259 |
| 73.1 | 1.8494E+05 | 1.18E+06 | 2.77E+05 | 0.2317 | 2.2 | 0.005 | 1398 |
| 74.1 | 1.9289E+05 | 1.30E+06 | 2.79E+05 | 0.2421 | 1.9 | 0.005 | 1329 |
| 75.1 | 1.7518E+05 | 1.30E+06 | 3.05E+06 | 0.1926 | 2.2 | 0.005 | 1354 |
| 76.1 | 2.0990E+05 | 1.30E+06 | 3.48E+05 | 0.2116 | 2.2 | 0.005 | 1398 |
| 77.1 | 2.0994E+05 | 1.31E+06 | 2.77E+05 | 0.2008 | 2.2 | 0.005 | 1489 |
| 78.1 | 2.1926E+05 | 4.18E+06 | 2.78E+05 | 0.2227 | 2.2 | 0.005 | 1448 |
| 79.1 | 2.2017E+05 | 4.18E+06 | 3.05E+05 | 0.2587 | 2.2 | 0.005 | 1479 |
| 80.1 | 2.2313E+05 | 4.18E+06 | 3.48E+06 | 0.2233 | 2.4 | 0.005 | 1508 |
| 81.1 | 2.4039E+05 | 4.18E+06 | 3.14E+05 | 0.2333 | 2.4 | 0.005 | 1538 |
| 82.2 | 2.3760E+05 | 4.18E+06 | 3.38E+06 | 0.2058 | 2.4 | 0.005 | 1578 |
| 83.1 | 2.4216E+05 | 4.18E+06 | 3.68E+05 | 0.4105 | 2.4 | 0.005 | 1579 |
| 84.1 | 2.5277E+05 | 4.18E+06 | 2.82E+05 | 0.2050 | 2.4 | 0.005 | 1570 |
| 85.1 | 2.5095E+05 | 4.18E+06 | 3.17E+05 | 0.1770 | 2.4 | 0.005 | 1579 |
| 86.1 | 2.6941E+05 | 4.18E+06 | 2.93E+05 | 0.1874 | 2.4 | 0.005 | 1680 |
| 87.1 | 2.5994E+05 | 1.43E+06 | 3.04E+05 | 0.2332 | 2.4 | 0.005 | 1699 |
| 88.1 | 2.7031E+05 | 1.61E+06 | 3.83E+05 | 0.1874 | 2.4 | 0.005 | 1099 |
| 89.1 | 2.6584E+05 | 1.60E+06 | 3.83E+06 | 0.2124 | 2.4 | 0.005 | 1718 |
| 90.1 | 2.5455E+05 | 1.54E+06 | 3.01E+05 | 0.1833 | 2.4 | 0.005 | 1740 |
| 91.4 | 2.6883E+05 | 1.55E+06 | 4.15E+06 | 0.2888 | 2.4 | 0.005 | 1770 |
| 92.1 | 2.8354E+05 | 1.73E+06 | 3.83E+05 | 0.2380 | 2.5 | 0.005 | 1800 |
| 83.1 | 3.0030E+05 | 1.65E+00 | 4.09E+06 | 0.2521 | 2.8 | 0.004 | 1808 |
| 94.1 | 3.0344E+05 | 1.88E+06 | 2.97E+06 | 0.1577 | 2.8 | 0.004 | 1929 |
| 95.1 | 2.0000E+05 | 1.82E+06 | 4.07E+06 | 0.2588 | 2.9 | 0.004 | 1959 |
| 96.1 | 3.2000E+05 | 2.00E+06 | 3.51E+06 | 0.1788 | 2.8 | 0.004 | 1966 |
| 97.1 | 3.7701E+05 | 1.87E+06 | 4.34E+06 | 0.2379 | 2.7 | 0.004 | 2618 |
| 98.1 | 3.3311E+05 | 2.06E+06 | 3.78E+06 | 0.1010 | 2.7 | 0.004 | 3946 |
| 99.1 | 2.3922E+05 | 2.08E+06 | 4.00E+06 | 0.2322 | 2.8 | 0.004 | 2036 |
| 100.1 | 3.0100E+05 | 2.24E+06 | 3.79E+06 | 0.1000 | 2.8 | 0.004 | 2168 |
| 101.1 | 3.9480E+05 | 2.30E+06 | 3.58E+06 | 0.1872 | 2.9 | 0.004 | 2136 |
| 102.1 | 3.5045E+05 | 2.33E+06 | 3.72E+06 | 0.1887 | 2.9 | 0.004 | 2188 |
| 103.1 | 3.8407E+05 | 2.38E+06 | 4.19E+06 | 0.1764 | 3.0 | 0.004 | 2196 |
| 104.1 | 3.0700E+05 | 2.20E+06 | 4.00E+06 | 0.1756 | 2.9 | 0.004 | 2236 |
| 105.1 | 3.7390E+05 | 2.21E+06 | 4.15E+06 | 0.1787 | 3.0 | 0.004 | 2288 |
| 106.1 | 3.8589E+05 | 2.39E+06 | 4.18E+06 | 0.1751 | 3.0 | 0.004 | 2386 |
| 107.1 | 3.8921E+05 | 2.40E+06 | 4.94E+06 | 0.2063 | 3.0 | 0.004 | 2318 |
| 108.1 | 3.7957E+05 | 2.88E+06 | 3.00E+06 | 0.1859 | 3.0 | 0.004 | 2348 |
| 109.1 | 3.9710E+05 | 2.48E+06 | 3.85E+06 | 0.1579 | 3.1 | 0.004 | 3378 |
| 110.1 | 3.9625E+05 | 2.48E+06 | 4.80E+06 | 0.3881 | 3.1 | 0.004 | 2408 |
| 111.1 | 3.9282E+05 | 2.41E+06 | 5.27E+06 | 0.2106 | 3.1 | 0.004 | 2138 |
| 112.1 | 4.0364E+05 | 2.48E+06 | 4.66E+06 | 0.1888 | 3.1 | 0.004 | 3168 |
| 113.1 | 4.0558E+05 | 2.49E+06 | 5.25E+06 | 0.2106 | 3.1 | 0.004 | 3488 |
| 114.1 | 4.2036E+05 | 2.66E+06 | 6.44E+06 | 0.2513 | 3.1 | 0.004 | 2528 |
| 115.1 | 3.7024E+05 | 2.20E+06 | 6.78E+06 | 0.2884 | 3.0 | 0.004 | 2568 |
| 116.1 | 3.0045E+05 | 2.21E+06 | 8.57E+06 | 0.2846 | 3.0 | 0.004 | 2558 |
| 117.1 | 3.0275E+05 | 2.38E+06 | 8.47E+06 | 0.2554 | 3.1 | 0.004 | 2015 |
| 118.1 | 4.0287E+05 | 2.47E+06 | 6.60E+06 | 0.2202 | 3.1 | 0.004 | 2548 |
| 119.4 | 3.5540E+05 | 2.14E+06 | 7.08E+06 | 0.3312 | 3.0 | 0.004 | 2666 |
| 120.1 | 3.2441E+05 | 1.93E+06 | 6.88E+06 | 0.3235 | 2.0 | 0.004 | 2708 |
| 121.1 | 3.5070E+05 | 2.11E+06 | 6.18E+06 | 0.2524 | 3.0 | 0.004 | 2730 |
| 122.1 | 3.5577E+05 | 2.11E+06 | 7.38E+06 | 0.2447 | 3.0 | 0.004 | 3758 |
| 123.1 | 3.7752E+05 | 2.24E+06 | 6.18E+06 | 0.3644 | 3.1 | 0.004 | 2850 |
| 124.1 | 3.8358E+05 | 2.33E+06 | 6.70E+06 | 0.2003 | 3.1 | 0.004 | 2850 |
| 125.1 | 3.7071E+05 | 2.24E+06 | 7.83E+06 | 0.3358 | 3.1 | 0.004 | 2858 |
| 126.1 | 4.3322E+05 | 2.00E+06 | 7.48E+06 | 0.2283 | 3.2 | 0.004 | 2868 |
| 127.1 | 4.3324E+05 | 2.00E+06 | 8.88E+06 | 0.2573 | 3.2 | 0.004 | 2018 |
| 128.1 | 4.2434E+05 | 2.57E+06 | 7.27E+06 | 0.2834 | 3.2 | 0.004 | 2548 |
| 129.1 | 4.8814E+05 | 2.08E+06 | 8.13E+06 | 0.3748 | 3.3 | 0.003 | 2379 |
| 130.1 | 4.4286E+05 | 2.73E+06 | 9.43E+06 | 0.1958 | 3.3 | 0.004 | 3333 |
| 131.1 | 4.0851E+05 | 3.00E+06 | 9.06E+06 | 0.2242 | 3.2 | 0.003 | 3833 |
| 132.1 | 4.9657E+05 | 3.04E+06 | 6.67E+06 | 0.2297 | 3.2 | 0.004 | 3058 |
| 133.1 | 5.2278E+05 | 3.30E+06 | 4.88E+06 | 0.1481 | 3.2 | 0.003 | 3098 |
| 134.1 | 5.5636E+05 | 3.44E+06 | 6.38E+06 | 0.1856 | 3.4 | 0.003 | 3129 |
| 135.1 | 4.6433E+05 | 2.84E+06 | 8.75E+06 | 0.2288 | 3.3 | 0.004 | 3158 |
| 136.1 | 4.9847E+05 | 2.10E+06 | 4.74E+06 | 0.1533 | 3.4 | 0.004 | 3158 |
| 137.1 | 4.7057E+05 | 2.00E+06 | 5.58E+06 | 0.1831 | 2.2 | 0.004 | 3218 |
| 138.1 | 4.4201E+05 | 2.23E+06 | 6.22E+06 | 0.1347 | 3.1 | 0.004 | 3248 |
| 139.1 | 3.9792E+05 | 2.44E+06 | 6.28E+06 | 0.2142 | 3.0 | 0.004 | 3278 |
| 140.0 | 3.6500E+05 | 2.25E+06 | 4.07E+06 | 0.2081 | 3.0 | 0.004 | 3308 |
| 141.0 | 3.4031E+05 | 2.10E+06 | 4.18E+06 | 0.1992 | 2.9 | 0.004 | 3338 |
| 142.0 | 3.1023E+05 | 1.00E+06 | 4.37E+06 | 0.2299 | 2.7 | 0.004 | 3355 |
| 143.0 | 2.8000E+05 | 1.00E+06 | 4.82E+06 | 0.3834 | 2.0 | 0.004 | 3398 |
| 144.2 | 2.8831E+05 | 1.74E+06 | 4.36E+06 | 0.2605 | 2.7 | 0.004 | 3428 |
| 145.3 | 3.0705E+05 | 1.00E+06 | 4.37E+06 | 0.2210 | 2.7 | 0.004 | 3456 |
| 146.3 | 3.8100E+05 | 2.00E+06 | 5.77E+06 | 0.2680 | 3.8 | 0.004 | 3483 |
| 147.2 | 4.3800E+05 | 2.80E+06 | 4.13E+06 | 0.1000 | 3.1 | 0.004 | 3518 |
| 148.2 | 8.0138E+05 | 2.00E+06 | 7.04E+06 | 0.2503 | 3.8 | 0.004 | 3348 |
| 149.1 | 8.0775E+05 | 2.06E+06 | 4.00E+06 | 0.0861 | 3.7 | 0.004 | 3878 |
| 150.1 | 1.0404E+05 | 0.67E+06 | 4.06E+06 | 0.1759 | 4.1 | 0.002 | 3308 |
| 151.1 | 1.0744E+05 | 6.73E+06 | 3.27E+06 | 0.1790 | 4.1 | 0.002 | 3636 |
| 152.1 | 1.2778E+05 | 8.00E+06 | 3.21E+06 | 0.0400 | 4.2 | 0.002 | 3966 |
| 153.1 | 1.8035E+05 | 1.00E+07 | 1.23E+06 | 0.1233 | 4.2 | 0.001 | 3558 |
| 154.2 | 1.0000E+05 | 1.04E+07 | −1.80E+06 | −0.0153 | 4.2 | 0.001 | 3731 |
| 155.3 | 1.0000E+05 | 1.01E+07 | −1.84E+06 | −0.3028 | 4.1 | 0.001 | 3758 |
| 156.1 | 1.8630E+05 | 1.17E+07 | 4.00E+06 | 0.0368 | 4.2 | 0.001 | 3786 |
| 157.1 | 1.6303E+05 | 1.02E+07 | 1.00E+06 | 0.0181 | 4.2 | 0.001 | 3918 |
| 158.1 | 1.6798E+05 | 1.02E+07 | −2.88E+06 | −0.2001 | 4.3 | 0.001 | 3848 |
| 159.1 | 1.7288E+05 | 1.09E+07 | 2.00E+06 | 0.0188 | 4.4 | 0.001 | 3879 |
| 160.1 | 1.7563E+05 | 1.10E+07 | 1.00E+06 | 0.0988 | 4.5 | 0.001 | 3908 |
| 161.1 | 1.7700E+05 | 1.11E+07 | −2.00E+06 | −0.0323 | 4.5 | 0.001 | 3339 |
| 162.1 | 1.7700E+05 | 1.12E+07 | −2.70E+06 | −0.0240 | 4.5 | 0.001 | 3968 |
| 163.1 | 1.5430E+05 | 9.08E+07 | −4.77E+06 | −0.0433 | 4.4 | 0.001 | 3398 |
| 164.1 | 2.0000E+05 | 1.26E+07 | −1.86E+06 | −0.1420 | 4.6 | 0.001 | 4329 |
| 165.1 | 1.8598E+05 | 1.17E+07 | −6.00E+06 | −0.0515 | 4.5 | 0.001 | 4358 |
| 166.1 | 1.6581E+05 | 1.03E+07 | −1.00E+06 | −0.1547 | 4.5 | 0.001 | 4085 |
| 167.1 | 1.9635E+05 | 1.24E+07 | −0.33E+06 | −0.0500 | 4.5 | 0.001 | 4118 |
| 168.1 | 1.9305E+05 | 1.21E+07 | 3.00E+06 | 0.0329 | 4.5 | 0.001 | 4148 |
| 169.1 | 2.2090E+05 | 1.38E+07 | 2.00E+06 | 0.0100 | 4.6 | 0.001 | 4179 |
| 170.1 | 1.9955E+05 | 1.25E+07 | 0.07E+06 | 0.0700 | 4.5 | 0.001 | 4203 |

### Example 1

| | (94.5% metal by weight) | | | | |
|---|---|---|---|---|---|
| Formulations: | Actual | | Density | Vol | |
| Chemical | Wt (g) | Wt % | (g/cm³) | (cm³) | Vol % |
| Resin Mix: | | | | | |
| EPON 862 | 1.874 | 45.66% | 1.170 | 1.602 | 45.02% |
| EPON 824 | 0.848 | 20.66% | 1.150 | 0.737 | 20.73% |
| MHHPA | 1.250 | 30.46% | 1.155 | 1.082 | 30.42% |
| AGE | 0.132 | 3.22% | 0.970 | 0.136 | 3.83% |
| tBPGE | 0.000 | 0.00% | 1.038 | 0.000 | 0.00% |
| Total Polymer Weight | 4.104 | | | | |
| Total Polymer Volume | | | | 3.557 | |
| Estimated Density Resin | | | 1.155 | | |
| Mix | | | | | |
| Metal Mix: | | | | | |
| In48Sn | 3.160 | 8.32% | 7.300 | 0.433 | 10.67% |
| Bi58Sn | 10.720 | 28.22% | 8.560 | 1.252 | 30.88% |
| Ag Technic | 4.300 | 11.32% | 10.500 | 0.410 | 10.10% |
| Ag Metalor | 14.850 | 39.09% | 10.500 | 1.414 | 34.87% |
| Ag Ferro | 4.960 | 13.06% | 9.074 | 0.547 | 13.48% |
| Total Metal Weight | 37.990 | | | | |
| Total Metal Volume | | | | 4.056 | |
| Estimated Density Metal | | | 9.500 | | |
| Mix | | | | | |
| Paste Mix: | | | | | |
| Wt % Polymer Mix | | 5.500 | | | |
| Wt % Metal Mix | | 94.500 | | | |
| Total Polymer Vol % | | | | 4.762 | 32.38% |
| Total Metal Vol % | | | | 9.947 | 67.62% |
| | | | | 14.710 | |

| Pot Life (hrs) | TC (W/m-K) | TI (cm² K/W) | Viscosity (cps at 25° C.) |
|---|---|---|---|
| ~3 | 14.0 | 0.033 | 180,000 |

### Example 2

| | (94%, 3% AGE) | | | | |
|---|---|---|---|---|---|
| Formulations: | Actual | | Density | Vol | |
| Chemical | Wt (g) | Wt % | (g/cm³) | (cm³) | Vol % |
| Resin Mix: | | | | | |
| EPON 862 | 1.874 | 45.66% | 1.170 | 1.602 | 45.02% |
| EPON 824 | 0.848 | 20.66% | 1.150 | 0.737 | 20.73% |
| MHHPA | 1.250 | 30.46% | 1.155 | 1.082 | 30.42% |
| AGE | 0.132 | 3.22% | 0.970 | 0.136 | 3.83% |
| tBPGE | 0.000 | 0.00% | 1.038 | 0.000 | 0.00% |
| Total Polymer Weight | 4.104 | | | | |
| Total Polymer Volume | | | | 3.557 | |
| Estimated Density Resin | | | 1.155 | | |
| Mix | | | | | |
| Metal Mix: | | | | | |
| In48Sn | 3.160 | 8.32% | 7.300 | 0.433 | 10.67% |
| Bi58Sn | 10.720 | 28.22% | 8.560 | 1.252 | 30.88% |
| Ag Technic | 4.300 | 11.32% | 10.500 | 0.410 | 10.10% |
| Ag Metalor | 14.850 | 39.09% | 10.500 | 1.414 | 34.87% |
| Ag Ferro | 4.960 | 13.06% | 9.074 | 0.547 | 13.48% |
| Total Metal Weight | 37.990 | | | | |
| Total Metal Volume | | | | 4.056 | |
| Estimated Density Metal | | | 9.500 | | |
| Mix | | | | | |
| Paste Mix: | | | | | |
| Wt % Polymer Mix | | 6.000 | | | |
| Wt % Metal Mix | | 94.000 | | | |
| Total Polymer Vol % | | | | 5.195 | 34.43% |
| Total Metal Vol % | | | | 9.895 | 65.57% |
| | | | | 15.090 | |

| Pot Life (hrs) | TC (W/m-K) | TI (cm² K/W) | Viscosity (cps at 25° C.) |
|---|---|---|---|
| ~4 | 11.6 | 0.037 | 154,000 |

### Example 3

| Formulations: | Actual | | Density | Vol | |
|---|---|---|---|---|---|
| Chemical | Wt (g) | Wt % | (g/cm³) | (cm³) | Vol % |
| Resin Mix: | | | | | |
| EPON 862 | 2.065 | 41.30% | 1.170 | 1.765 | 40.34% |
| EPON 824 | 0.935 | 18.70% | 1.150 | 0.813 | 18.58% |
| MHHPA | 1.500 | 30.00% | 1.155 | 1.299 | 29.68% |
| AGE | 0.250 | 5.00% | 0.970 | 0.258 | 5.89% |
| tBPGE | 0.250 | 5.00% | 1.038 | 0.241 | 5.50% |
| Total Polymer Weight | 5.000 | | | | |
| Total Polymer Volume | | | | 4.375 | |
| Estimated Density Resin | | | 1.145 | | |
| Mix | | | | | |
| Metal Mix: | | | | | |
| In48Sn | 3.160 | 8.32% | 7.300 | 0.433 | 10.67% |
| Bi58Sn | 10.720 | 28.22% | 8.560 | 1.252 | 30.88% |
| Ag Technic | 4.300 | 11.32% | 10.500 | 0.410 | 10.10% |
| Ag Metalor | 14.850 | 39.09% | 10.500 | 1.414 | 34.87% |
| Ag Ferro | 4.960 | 13.06% | 9.074 | 0.547 | 13.48% |
| Total Metal Weight | 37.990 | | | | |
| Total Metal Volume | | | | 4.056 | |
| Estimated Density Metal | | | 9.500 | | |
| Mix | | | | | |
| Paste Mix: | | | | | |
| Wt % Polymer Mix | | 6.000 | | | |
| Wt % Metal Mix | | 94.000 | | | |
| Total Polymer Vol % | | | | 5.239 | 34.62% |
| Total Metal Vol % | | | | 9.895 | 65.38% |
| | | | | 15.134 | |

| Pot Life (hrs) | TC (W/m-K) | TI (cm² K/W) | Viscosity (cps at 25° C.) |
|---|---|---|---|
| | | 0.039 | |

### Example 4

| | 93.75% metal, 18.5% tBPGE | | | | |
|---|---|---|---|---|---|
| Formulations: | Actual | | Density | Vol | |
| Chemical | Wt (g) | Wt % | (g/cm³) | (cm³) | Vol % |
| Resin Mix: | | | | | |
| EPON 862 | 1.874 | 38.44% | 1.170 | 1.602 | 37.33% |
| EPON 824 | 0.848 | 17.39% | 1.150 | 0.737 | 17.18% |
| MHHPA | 1.251 | 25.66% | 1.155 | 1.083 | 25.24% |
| AGE | 0 | 0.00% | 0.970 | 0.000 | 0.00% |
| tBPGE | 0.902 | 18.50% | 1.038 | 0.869 | 20.25% |
| Total Polymer Weight | 4.875 | | | | |
| Total Polymer Volume | | | | 4.291 | |
| Estimated Density Resin | | | 1.138 | | |
| Mix | | | | | |
| Metal Mix: | | | | | |
| In48Sn | 3.160 | 8.32% | 7.300 | 0.433 | 10.67% |
| Bi58Sn | 10.720 | 28.22% | 8.560 | 1.252 | 30.88% |
| Ag Technic | 4.300 | 11.32% | 10.500 | 0.410 | 10.10% |
| Ag Metalor | 14.850 | 39.09% | 10.500 | 1.414 | 34.87% |
| Ag Ferro | 4.960 | 13.06% | 9.074 | 0.547 | 13.48% |
| Total Metal Weight | 37.990 | | | | |
| Total Metal Volume | | | | 4.056 | |
| Estimated Density Metal | | | 9.500 | | |
| Mix | | | | | |
| Paste Mix: | | | | | |
| Wt % Polymer Mix | | 6.300 | | | |
| Wt % Metal Mix | | 93.700 | | | |
| Total Polymer Vol % | | | | 5.535 | 35.95% |
| Total Metal Vol % | | | | 9.863 | 64.05% |
| | | | | 15.398 | |

| Pot Life (hrs) | TC (W/m-K) | TI (cm² K/W) | Viscosity (cps at 25° C.) |
|---|---|---|---|
| ~12 | 10.9 | 0.041 | 104,404 |

### Example 5

| | (93.5% metal, 25% tBPGE) | | | | |
|---|---|---|---|---|---|
| Formulations: | Actual | | Density | Vol | |
| Chemical | Wt (g) | Wt % | (g/cm³) | (cm³) | Vol % |
| Resin Mix: | | | | | |
| EPON 862 | 1.721 | 34.43% | 1.170 | 1.471 | 33.17% |
| EPON 824 | 0.778 | 15.56% | 1.150 | 0.677 | 15.26% |
| MHHPA | 1.250 | 25.01% | 1.155 | 1.082 | 24.41% |
| AGE | 0.000 | 0.00% | 0.970 | 0.000 | 0.00% |
| tBPGE | 1.250 | 25.01% | 1.038 | 1.204 | 27.16% |
| Total Polymer Weight | 4.999 | | | | |
| Total Polymer Volume | | | | 4.434 | |
| Estimated Density Resin | | | 1.130 | | |
| Mix | | | | | |
| Metal Mix: | | | | | |
| In48Sn | 3.160 | 8.32% | 7.300 | 0.433 | 10.67% |
| Bi58Sn | 10.720 | 28.22% | 8.560 | 1.252 | 30.88% |
| Ag Technic | 4.300 | 11.32% | 10.500 | 0.410 | 10.10% |
| Ag Metalor | 14.850 | 39.09% | 10.500 | 1.414 | 34.87% |
| Ag Ferro | 4.960 | 13.06% | 9.074 | 0.547 | 13.48% |
| Total Metal Weight | 37.990 | | | | |
| Total Metal Volume | | | | 4.056 | |
| Estimated Density Metal | | | 9.500 | | |
| Mix | | | | | |
| Paste Mix: | | | | | |
| Wt % Polymer Mix | | 6.500 | | | |
| Wt % Metal Mix | | 93.500 | | | |
| Total Polymer Vol % | | | | 5.752 | 36.88% |
| Total Metal Vol % | | | | 9.842 | 63.12% |
| | | | | 15.593 | |

| Pot Life (hrs) | TC (W/m-K) | TI (cm² K/W) | Viscosity (cps at 25° C.) |
|---|---|---|---|
| ~14 | 12.6 | 0.033 | 71,702 |

### Example 6

| | (93.5% metal, 30% tBPGE) | | | | |
|---|---|---|---|---|---|
| Formulations: | Actual | | Density | Vol | |
| Chemical | Wt (g) | Wt % | (g/cm³) | (cm³) | Vol % |
| Resin Mix: | | | | | |
| EPON 862 | 1.721 | 34.43% | 1.170 | 1.471 | 32.99% |
| EPON 824 | 0.778 | 15.56% | 1.150 | 0.677 | 15.17% |
| MHHPA | 1.000 | 20.00% | 1.155 | 0.866 | 19.42% |
| AGE | 0.000 | 0.00% | 0.970 | 0.000 | 0.00% |
| tBPGE | 1.500 | 30.01% | 1.038 | 1.445 | 32.41% |
| Total Polymer Weight | 4.999 | | | | |
| Total Polymer Volume | | | | 4.458 | |
| Estimated Density Resin | | | 1.124 | | |
| Mix | | | | | |
| Metal Mix: | | | | | |
| In48Sn | 3.160 | 8.32% | 7.300 | 0.433 | 10.67% |
| Bi58Sn | 10.720 | 28.22% | 8.560 | 1.252 | 30.88% |
| Ag Technic | 4.300 | 11.32% | 10.500 | 0.410 | 10.10% |
| Ag Metalor | 14.850 | 39.09% | 10.500 | 1.414 | 34.87% |
| Ag Ferro | 4.960 | 13.06% | 9.074 | 0.547 | 13.48% |
| Total Metal Weight | 37.990 | | | | |
| Total Metal Volume | | | | 4.056 | |
| Estimated Density Metal | | | 9.500 | | |
| Mix | | | | | |
| Paste Mix: | | | | | |
| Wt % Polymer Mix | | 6.500 | | | |
| Wt % Metal Mix | | 93.500 | | | |
| Total Polymer Vol % | | | | 5.781 | 37.01% |
| Total Metal Vol % | | | | 9.842 | 62.99% |
| | | | | 15.623 | |

| Pot Life (hrs) | TC (W/m-K) | TI (cm² K/W) | Viscosity (cps at 25° C.) |
|---|---|---|---|
| ~12 | 11.8 | 0.041 | 74,664 |

Examples 1-6 show a good balance of properties, including low viscosity, high thermal conductivity, good reliability and good pot life. All of Examples 1-6 provide at least a minimal amount of balance between those characteristics. The preferred use of AGE and/or tBPGE demonstrates that balance.

In Examples 1 and 2, AGE was used, but not tBPGE. Thus, those Examples provided a good balance. However, utilization of tBPGE instead of AGE provided even more enhanced results as indicated in Examples 4, 5 and 6. Example 3 shows a utilization of both AGE and tBPGE which also provides an excellent balance of thermal conductivity, reliability, viscosity and pot life. Thus, we have discovered that formulations having a viscosity of less than about 200,000 cps, thermal impedance of about 0.05 cm² K/W or less, thermal conductivity of about 15 W/m-K or less and a pot life of 3 or more hours, preferably at least about 12 hours, allows for the production of thermal interface materials that are capable of a wide use of applications.

Thus, representative examples and applications of thermal interface materials, methods of production and uses thereof have been disclosed. It should be apparent, however, to those skilled in the art that many more modifications besides those already described are possible without departing from the inventive concepts herein. The inventive subject matter, therefore, is not to be restricted except in the spirit of the disclosure. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

1. A composition comprising:
an epoxy polymeric matrix;
a conductive filler;
a solder material; and
a matrix material modification agent including a viscosity modifying component to reduce the viscosity of the epoxy polymeric matrix;
wherein the composition has a viscosity of 100,000 cps or less at 25° C.

2-4. (canceled)

5. The composition according to claim 1, wherein the conductive filler is at least one selected from the group consisting of tin, bismuth, indium, bismuth-tin alloy, silver metals and indium-tin alloy.

6. The composition according to claim 1, comprising about 60 vol % to about 80 vol % of the conductive filler, based on the volume of the composition.

7. The composition according to claim 1, wherein the solder material is at least one selected from the group consisting of indium-tin alloys, indium-silver alloys, indium-bismuth alloys, tin-indium-bismuth alloys, indium-tin-silver-zinc alloys, indium-based alloys, tin-silver-copper alloys, tin-bismuth alloys, gallium compounds and gallium alloys.

8. The composition according to claim 1, comprising about 20 vol % to about 50 vol % of the solder, based on the volume of the composition.

9. The composition according to claim 1, wherein the matrix material modification agent further includes an end capping agent.

10. (canceled)

11. The composition of claim 1, wherein the matrix material modification agent is at least one selected from the group consisting of tBPGE and AGE.

12. The composition according to claim 11, wherein the matrix material modification agent is about 0 vol % to about 20 vol % tBPGE and about 0 vol % to about 5 vol % AGE, based on the volume of the composition.

13. (canceled)

14. A thermally transmissive electronic component comprising:
a first substrate;
a second substrate; and
a cured composition formed from the composition according to claim 1 positioned between the first and second substrates.

15-18. (canceled)

19. A method of producing a thermally transmissive electronic component comprising:
forming a curable thermal interface material by mixing an epoxy polymeric matrix, a conductive filler, a solder material and a matrix material modification agent including a viscosity modifying component that reduces the viscosity of the epoxy polymeric matrix, wherein the mixture has a viscosity of 100,000 cps or less at 25° C.;
positioning the composition between a first and a second substrate;
curing the polymeric matrix; and
applying heat to the matrix sufficient to at least partially melt at least a portion of the solder material such that the solder connects to particles in the filler to form a plurality of continuous heat transmissive pathways between the substrates and through the matrix.

20. The method according to claim 19, wherein the matrix is cured and the solder at least partially melted with heat between about 120° C. and about 170° C.
